(19) United States
(12) Patent Application Publication
(10) Pub. No.: US 2013/0168733 A1
(43) Pub. Date: Jul. 4, 2013

(54) SEMICONDUCTOR-STACKED SUBSTRATE, SEMICONDUCTOR CHIP, AND METHOD FOR PRODUCING SEMICONDUCTOR-STACKED SUBSTRATE

(71) Applicant: PANASONIC Corporation, Osaka (JP)

(72) Inventors: Junko IWANAGA, Osaka (JP); Songbaek CHOE, Osaka (JP); Toshiya YOKOGAWA, Nara (JP)

(73) Assignee: PANASONIC CORPORATION, Osaka (JP)

(21) Appl. No.: 13/739,867

(22) Filed: Jan. 11, 2013

Related U.S. Application Data
(63) Continuation of application No. PCT/JP2012/002708, filed on Apr. 19, 2012.

(30) Foreign Application Priority Data
Apr. 20, 2011 (JP) 2011-093736

(51) Int. Cl. H01L 29/205

(52) U.S. Cl. CPC H01L 29/205
USPC 257/190; 438/478

(57) ABSTRACT

Disclosed is a semiconductor-stacked substrate having a substrate, and a plurality of semiconductor layers which are different in thermal expansion coefficient from the substrate, and are formed in a plurality of regions of a surface of the substrate, respectively. Each semiconductor layer has a growth plane that is a nonpolar plane or a semi-polar plane, and has different thermal expansion coefficients between along a first axis and a second axis orthogonal to each other and parallel to the surface of the substrate. The following mathematical formula 1 is satisfied. D1 and ρ1 represent, respectively, the length and the curvature radius of the semiconductor layer in a direction which passes through a point where the deformation amount of the semiconductor layer is largest and is parallel to the first axis direction. D2 and ρ2 represent those of the second axis direction.

$$\begin{matrix}Mathematical formula 1 & \\ 0.8 D 1 \leq D 2 \frac{\sqrt{ρ 1}}{\sqrt{ρ 2}} \leq 1.2 D 1 & [ Math . 1 ]\end{matrix}$$

### TECHNICAL FIELD

The present invention relates to a semiconductor-stacked substrate and a semiconductor chip each having a plurality of semiconductor-stacked structures different in thermal expansion coefficient from a substrate thereof, and a method for producing the semiconductor-stacked substrate.

### BACKGROUND ART

Nitride semiconductors having nitrogen (N) as a Group V element have been regarded as being promising materials of short-wavelength light-emitting elements because of the magnitude of the band gap thereof. Of these semiconductors, gallium nitride based compound semiconductors (GaN based semiconductors) have been actively researched. Blue light-emitting diodes (LEDs), green LEDs, and semiconductor lasers each made of a GaN based semiconductor have also been put into practical use (see, for example, PTLs 1 and 2 listed below).

The GaN based semiconductors have a wurtzite type crystal structure. FIG. 1 illustrates unit lattices of GaN schematically. In a crystal of an AlₓGa_{y}In_{z}N semiconductor wherein x+y+z=1, x≧0, y≧0, and z≧0, Ga atoms illustrated in FIG. 1 may be partially substituted with Al and/or In atoms. FIG. 2 is a view showing four basic vectors a₁, a₂, a₃ and c used generally to represent a wurtzite type crystal structure plane by the four-index notation method (hexagonal indexes). The basic vector c is extended in the [0001] direction, and this direction is called the “c-axis”. A plane perpendicular to the c-axis is called the “c plane” or the “(0001) plane”. The “c-axis” and “c plane” may be denoted as the “C axis” and “C plane”, respectively.

As illustrated in FIGS. 3A to 3D, a wurtzite type crystal structure has typical crystal plane directions besides the c-plane. FIG. 3A shows a (0001) plane thereof. FIG. 3B shows a (10-10) plane thereof. FIG. 3C shows a (11-20) plane thereof. FIG. 3D shows a (10-12) plane of the wurtzite type crystal structure. The symbol “-” attached to the left of one of the numbers in each of the parenthesis pairs indicating Miller indices means “bar”. The (0001) plane, (10-10) plane, (11-20) plane, and (10-12) plane are the c-plane, the m-plane, the a-plane, and the r-plane, respectively. The m-plane and the a-plane are “nonpolar planes” parallel to the c-axis (basic vector c). However, the r-plane is a “semi-polar face plane”.

Over many years, light-emitting elements and electronic elements using the GaN based semiconductors have been produced by c-plane growth method. In the present specification, the wording “X-plane growth method” means that epitaxial growth is generated in a direction orthogonal to the X-plane (wherein X=c, m, a, r and so on) of a hexagonal wurtzite structure. In the X-plane growth method, the X-plane may be called “growth plane”. A layer of a semiconductor formed by the X-plane growth method may be called an “X-plane semiconductor layer”.

When a semiconductor-stacked structure formed by c-plane growth method is used to fabricate a light-emitting element or an electronic element, a strong internal polarization is generated in a direction (c-axis direction) orthogonal to the c-plane, since the c-plane is a polar plane. The reason why the polarization is generated is that, within the c-plane, the positions of Ga atoms and N atoms are shifted into the c-axis direction.

In the case of, for example, a light-emitting element, the generation of such polarization in its light-emitting part produces a quantum-confined Stark effect of carriers. This effect decreases the probability of re-combination of the carriers in the light-emitting part so that this element is declined in light-emitting efficiency.

To overcome this problem, in recent years, active researches have been made about the growth of a GaN based semiconductor onto a nonpolar plane, such as the m-plane or a-plane, or a semi-polar plane, such as the r-plane (see, for example, PTLs 3, 4 and 5).

### CITATION LIST

### Patent Literature

PTL 1: Unexamined Japanese Patent Publication No. 2001-308462
PTL 2: Unexamined Japanese Patent Publication No. 2003-332697
PTL 3: Unexamined Japanese Patent Publication No. 2003-63897
PTL 4: U.S. Pre-Grant Patent Publication No. 2009/0085055
PTL 5: Japanese Patent No. 2954743

### SUMMARY OF THE INVENTION

### Technical Problem

However, in the above-mentioned conventional techniques, a decrease in costs has been required.

In light of this matter, the present invention has been made, and a main object thereof is to decrease costs.

### Solutions to Problem

In an aspect disclosed in the present specification, a semiconductor-stacked substrate comprises: a substrate; and a plurality of semiconductor layers formed on a surface of the substrate. Each of the semiconductor layers has a growth plane that is a nonpolar plane or a semi-polar plane; and has different thermal expansion coefficients or stresses between along a first axis and a second axis which are orthogonal to each other; and the first axis and the second axis are parallel to the surface of the substrate. D1 represents a length of each of the semiconductor layers in a direction parallel to the first axis, the direction passing through a point where a deformation amount of each of the semiconductor layers is largest; D2 represents a length of each of the semiconductor layers in a direction parallel to the second axis, the direction passing through a point where a deformation amount of each of the semiconductor layers is greatest; ρ1 represents a curvature radius of each of the semiconductor layers in a direction parallel to the first axis, the direction passing through a point where a deformation amount of each of the semiconductor layers is greatest; and ρ2 represents a curvature radius of each of the semiconductor layers in a direction parallel to the second axis, the direction passing through a point where a deformation amount of each of the semiconductor layers is greatest. deformation amount deformation amount These D1, ρ1, D2 and ρ2 satisfy the following mathematical formula 1:

$$\begin{matrix}Mathematical formula 1 & \\ 0.8 D 1 \leq D 2 \frac{\sqrt{ρ 1}}{\sqrt{ρ 2}} \leq 1.2 D 1 & [ Math . 1 ]\end{matrix}$$

In another aspect disclosed in the specification, a semiconductor chip is produced by using the semiconductor layers of the semiconductor-stacked substrate to produce a plurality of semiconductor elements or semiconductor circuit elements, and dividing the semiconductor elements or semiconductor circuit elements from each other.

In still another aspect disclosed in the specification, a semiconductor-stacked substrate producing method is a method for producing a semiconductor-stacked substrate comprising a substrate and a plurality of semiconductor layers. The method comprises a step (A) of forming, on the substrate, a mask having a plurality of openings; and a step (B) of forming the plurality of semiconductor layers in the plurality of openings. In the step (A), each of the semiconductor layers has a growth plane that is a nonpolar plane or a semi-polar plane, each of the semiconductor layers has different thermal expansion coefficients or stresses between along a first axis and a second axis which are orthogonal to each other, and the first axis and the second axis are parallel to the surface of the substrate. D1 represents a length of each of the semiconductor layers in a direction parallel to the first axis; D2 represents a length of each of the semiconductor layers in a direction parallel to the second axis; ρ1 represents a curvature radius of each of the semiconductor layers in a direction parallel to the first axis; and ρ2 represents a curvature radius of each of the semiconductor layers in a direction parallel to the second axis. These D1, ρ1, D2 and ρ2 satisfy the following mathematical formula 2:

$$\begin{matrix}Mathematical formula 2 & \\ 0.8 D 1 \leq D 2 \frac{\sqrt{ρ 1}}{\sqrt{ρ 2}} \leq 1.2 D 1 & [ Math . 2 ]\end{matrix}$$

### Advantageous Effect of Invention

According to the aspects disclosed in the specification, costs can be decreased.

### BRIEF DESCRIPTION OF DRAWINGS

FIG. 1 is a view illustrating unit lattices of GaN schematically.

FIG. 2 is a view showing four basic vectors a₁, a₂, a₃ and c used generally to represent a wurtzite type crystal structure by the four-index notation method (hexagonal indexes).

FIG. 3A is a (0001) plane of the wurtzite type crystal structure.

FIG. 3B is a (10-10) plane of the wurtzite type crystal structure.

FIG. 3C is a (11-20) plane of the wurtzite type crystal structure.

FIG. 3D is a (10-12) plane of the wurtzite type crystal structure.

FIG. 4A is a cross-sectional view of a semiconductor-stacked substrate.

FIG. 4B is a cross-sectional view illustrating a stacked structure wherein light-emitting diode elements are formed on the semiconductor-stacked substrate illustrated in FIG. 4A.

FIG. 4C is a cross-sectional view illustrating a stacked structure wherein a semiconductor chip is formed by working semiconductor-stacked substrate in which the light-emitting diode elements are formed and are illustrated in FIG. 4B.

FIG. 5 is a cross-sectional view illustrating a semiconductor-stacked substrate.

FIG. 6A is a cross-sectional view illustrating a step of forming a semiconductor-stacked substrate in a process of producing semiconductor elements.

FIG. 6B is a top-view illustrating a principal surface of the semiconductor-stacked substrate in FIG. 6A.

FIG. 6C is a cross-sectional view illustrating a step of forming a semiconductor layer.

FIG. 6D is a cross-sectional view illustrating a semiconductor wafer wherein semiconductor elements have been formed.

FIG. 7A is a cross-sectional view of a semiconductor-stacked substrate wherein a semiconductor layer is formed onto the whole of a surface of a substrate.

FIG. 7B is a cross-sectional view of a semiconductor-stacked substrate wherein a semiconductor layer is selectively grown onto a substrate.

FIG. 8A is a view illustrating a principal surface of a semiconductor-stacked substrate.

FIG. 8B is a schematic view illustrating the shape of the semiconductor layer on the surface of the substrate, and is a view obtained when the section is obliquely viewed from above.

FIG. 8C is a schematic view illustrating the shape of the semiconductor layer on the surface of the substrate, and is a view obtained when the section is obliquely viewed from above.

FIG. 9A is a view showing directions of crystal axes obtained when an m-plane GaN semiconductor layer is grown onto an m-plane sapphire substrate by crystal growth.

FIG. 9B is a view showing directions of crystal axes obtained when an m-plane GaN semiconductor layer is grown onto an a-plane sapphire substrate by crystal growth.

FIG. 10A is a view illustrating a principal surface of a semiconductor-stacked substrate of the exemplary embodiment 1 according to the present invention.

FIG. 10B is a cross-sectional view along the line 10B-10B included in FIG. 10A.

FIG. 10C is a cross-sectional view along the line 10C-10C included in FIG. 10A.

FIG. 11A is a view illustrating a principal surface of a semiconductor layer in the exemplary embodiment 1 according to the present invention.

FIG. 11B is a cross-sectional view along the line 11B-11B included in FIG. 11A.

FIG. 11C is a cross-sectional view along the line 11C-11C included in FIG. 11A.

FIG. 12A is a view illustrating a method for producing the semiconductor-stacked substrate of the exemplary embodiment 1 according to the present invention.

FIG. 12B is a view illustrating the method for producing the semiconductor-stacked substrate of the exemplary embodiment 1 according to the present invention.

FIG. 12C is a view illustrating the method for producing the semiconductor-stacked substrate of the exemplary embodiment 1 according to the present invention.

FIG. 12D is a view illustrating the method for producing the semiconductor-stacked substrate of the exemplary embodiment 1 according to the present invention.

FIG. 13A is a view illustrating a principal surface demonstrating a modified example of the semiconductor-stacked substrate of the exemplary embodiment 1 according to the present invention.

FIG. 13B is a view illustrating a principal surface demonstrating a modified example of the semiconductor-stacked substrate of the exemplary embodiment 1 according to the present invention.

FIG. 13C is a view illustrating a principal surface demonstrating a modified example of the semiconductor-stacked substrate of the exemplary embodiment 1 according to the present invention.

FIG. 13D is a view illustrating a principal surface demonstrating a modified example of the semiconductor-stacked substrate of the exemplary embodiment 1 according to the present invention.

FIG. 13E is a view illustrating a principal surface demonstrating a modified example of the semiconductor-stacked substrate of the exemplary embodiment 1 according to the present invention.

FIG. 14A is a view illustrating a principal surface of a semiconductor wafer of the exemplary embodiment 3 according to the present invention.

FIG. 14B is a view illustrating a principal surface of semiconductor region 16 included in FIG. 14A.

FIG. 15A is a cross-sectional view illustrating a partial region of the cross section taken along the line 15A-15A included in FIG. 14B.

FIG. 15B is a cross-sectional view of a semiconductor chip of the exemplary embodiment 3 according to the present invention.

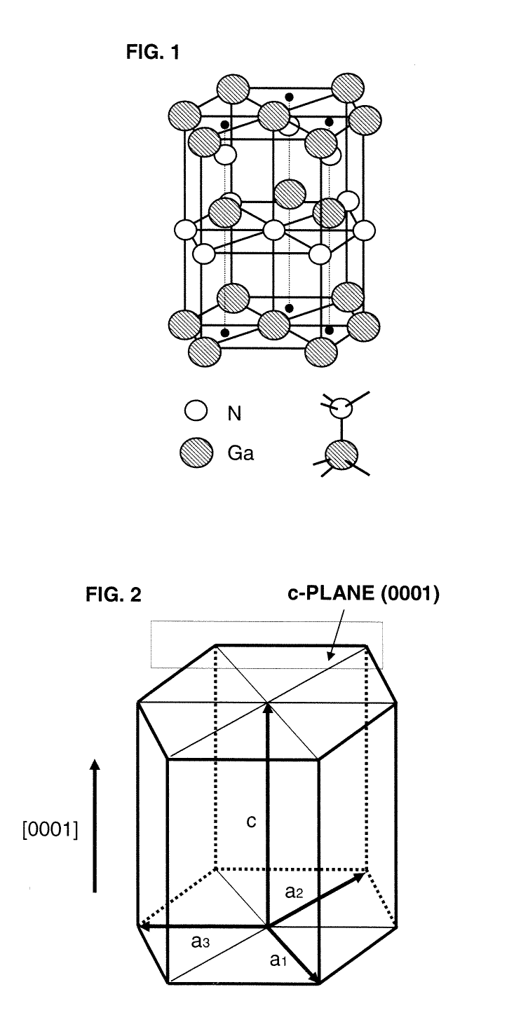

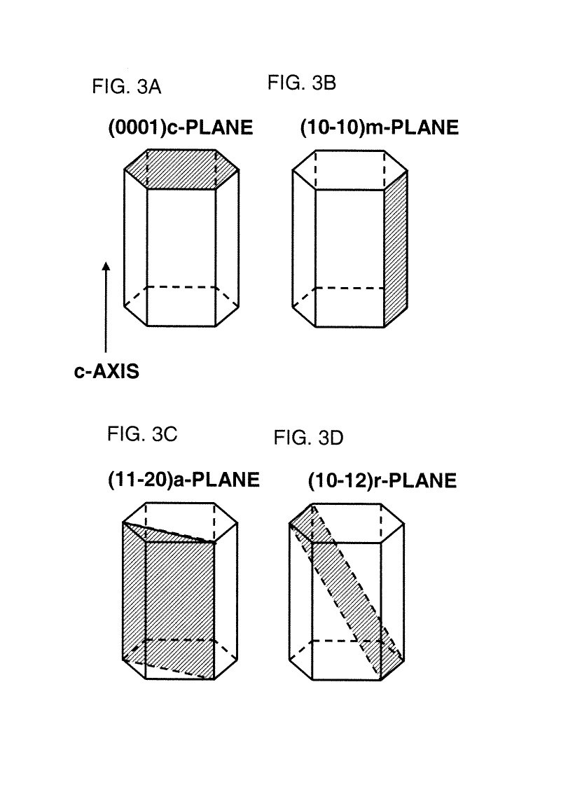

### DESCRIPTION OF EMBODIMENTS

In an embodiment disclosed in the present specification, a semiconductor-stacked substrate comprises: a substrate; and a plurality of semiconductor layers each different in thermal expansion coefficient from the substrate, and formed on a surface of the substrate. Each of the semiconductor layers has a growth plane that is a nonpolar plane or a semi-polar plane; each of the semiconductor layers has different thermal expansion coefficients between along a first axis and a second axis which are orthogonal to each other; and the first axis and the second axis are parallel to the surface of the substrate. The following mathematical formula 1 is satisfied:

$$\begin{matrix}Mathematical formula 1 & \\ 0.8 D 1 \leq D 2 \frac{\sqrt{ρ 1}}{\sqrt{ρ 2}} \leq 1.2 D 1 & [ Math . 1 ]\end{matrix}$$

where D1 represents a length of each of the semiconductor layers in a direction parallel to the first axis, the direction passing through a point where a deformation amount of each of the semiconductor layers is largest; D2 represents a length of each of the semiconductor layers in a direction parallel to the second axis, the direction passing through a point where a deformation amount of each of the semiconductor layers is greatest; ρ1 represents a curvature radius of each of the semiconductor layers in a direction parallel to the first axis, the direction passing through a point where a deformation amount of each of the semiconductor layers is greatest; and ρ2 represents a curvature radius of each of the semiconductor layers in a direction parallel to the second axis, the direction passing through a point where a deformation amount of each of the semiconductor layers is greatest.

In an embodiment, a semiconductor-stacked substrate comprises: a substrate; and a plurality of semiconductor layers formed on a surface of the substrate. Each of the semiconductor layers has a growth plane that is a nonpolar plane or a semi-polar plane. Different stresses are generated between along a first axis and a second axis which are orthogonal to each other and the first axis and the second axis are parallel to the surface of the substrate. The following mathematical formula 1 is satisfied:

$$\begin{matrix}Mathematical formula 1 & \\ 0.8 D 1 \leq D 2 \frac{\sqrt{ρ 1}}{\sqrt{ρ 2}} \leq 1.2 D 1 & [ Math . 1 ]\end{matrix}$$

where D1 represents a length of each of the semiconductor layers in a direction parallel to the first axis, the direction passing through a point where a deformation amount of each of the semiconductor layers is largest; D2 represents a length of each of the semiconductor layers in a direction parallel to the second axis, the direction passing through a point where a deformation amount of each of the semiconductor layers is greatest; ρ1 represents a curvature radius of each of the semiconductor layers in a direction parallel to the first axis, the direction passing through a point where a deformation amount of each of the semiconductor layers is greatest; and ρ2 represents a curvature radius of each of the semiconductor layers in a direction parallel to the second axis, the direction passing through a point where a deformation amount of each of the semiconductor layers is greatest. In an embodiment, the stresses include distortion stress.

In an embodiment, the lengths D1 and D2 are different from each other, and radii ρ1 and ρ2 are different from each other.

In an embodiment, a ratio D1/D2 of the length D1 to the length D2 is defined as the following mathematical formula 3:

$$\begin{matrix}Mathematical formula 3 & \\ \frac{D 1}{D 2} = \frac{\sqrt{ρ 1}}{\sqrt{ρ 2}} & [ Math . 3 ]\end{matrix}$$

In an embodiment, the length D1 is defined, using the radius ρ1 and the maximum deformation amount Hₘₐₓ of each of the semiconductor layers as the following mathematical formula 4:

[Math. 4]

D1≅\sqrt{8Hₘₐₓρ1} Mathematical formula 4

In an embodiment, the length D2 is defined, using the radius ρ2 and the maximum deformation amount Hₘₐₓ of each of the semiconductor layers as the following mathematical formula 5:

[Math. 5]

D2≅\sqrt{8Hₘₐₓρ2} Mathematical formula 5

In an embodiment, a center of each of the semiconductor layers has the maximum deformation amount Hₘₐₓ.

In an embodiment, the substrate is a sapphire substrate.

In an embodiment, the surface of the substrate is an m-plane, the first axis is an a-axis, and the second axis is a c-axis.

In an embodiment, the surface of the substrate is an a-plane, the first axis is an a-axis, and the second axis is a c-axis.

In an embodiment, the growth plane of the semiconductor layers is an m-plane, the first axis is an a-axis, and the second axis is a c-axis.

In an embodiment, the semiconductor layers are GaN based semiconductor layer sections.

In an embodiment, the semiconductor layers comprise AlₓGa_{y}In_{z}N wherein x+y+z=1, and x≧0, y≧0, and z≧0.

In an embodiment, the lengths D1 and D2 are each from 0.5 cm to 3 cm both inclusive.

In an embodiment, the lengths D1 and D2 are each from 2.8 cm to 12.5 cm both inclusive.

In an embodiment, when the surface of each of the semiconductor layers is viewed from above, the shape of the surface has two sides substantially parallel to the first axis, and two sides substantially parallel to the second axis.

In an embodiment, a semiconductor chip is produced by using the semiconductor layers of the semiconductor-stacked substrate to produce a plurality of semiconductor elements or semiconductor circuit elements, and dividing the semiconductor elements or semiconductor circuit elements from each other.

An embodiment disclosed in the present specification is a method for producing a semiconductor-stacked substrate comprising a substrate and a plurality of semiconductor layers each different in thermal expansion coefficient from the substrate. The semiconductor-stacked substrate producing method comprises a step (A) of forming, on the substrate, a mask having a plurality of openings; and a step (B) of forming the plurality of semiconductor layers in the plurality of openings. In the step (A), each of the semiconductor layers has a growth plane that is a nonpolar plane or a semi-polar plane; each of the semiconductor layers has different thermal expansion coefficients between along a first axis and a second axis which are orthogonal to each other; and the first axis and the second axis are parallel to the surface of the substrate. The following mathematical formula 2 is satisfied:

$$\begin{matrix}Mathematical formula 2 & \\ 0.8 D 1 \leq D 2 \frac{\sqrt{ρ 1}}{\sqrt{ρ 2}} \leq 1.2 D 1 & [ Math . 2 ]\end{matrix}$$

where D1 represents a length of each of the semiconductor layers in a direction parallel to the first axis; D2 represents a length of each of the semiconductor layers in a direction parallel to the second axis; ρ1 represents a curvature radius of each of the semiconductor layers in a direction parallel to the first axis; and ρ2 represents a curvature radius of each of the semiconductor layers in a direction parallel to the second axis.

An embodiment disclosed in the specification is a method for producing a semiconductor-stacked substrate comprising a substrate and a plurality of semiconductor layers. The semiconductor-stacked substrate producing method comprises a step (A) of forming, on the substrate, a mask having a plurality of openings; and a step (B) of forming the plurality of semiconductor layers in the plurality of openings. In the step (A), each of the semiconductor layers has a growth plane that is a nonpolar plane or a semi-polar plane; different stresses are generated between along a first axis and a second axis which are orthogonal to each other; and the first axis and the second axis are parallel to the surface of the substrate. The mathematical formula 2 is satisfied where D1 represents a length of each of the semiconductor layers in a direction parallel to the first axis; D2 represents a length of each of the semiconductor layers in a direction parallel to the second axis; ρ1 represents a curvature radius of each of the semiconductor layers in a direction parallel to the first axis; and ρ2 represents a curvature radius of each of the semiconductor layers in a direction parallel to the second axis.

Hereinafter, a description will be made centrally about a GaN semiconductor. However, substantially the same matters as stated in the description are applied to other GaN based semiconductors, nitride semiconductors, and other semiconductors.

When a nonpolar plane of a semiconductor can be selected as a growth plane, no polarization is generated in the layer thickness direction (crystal growing direction) of the light-emitting part (concerned), so that no quantum-confined Stark effect is generated. Thus, a light-emitting element which latently has a high efficiency can be produced. Even when a semi-polar plane thereof is selected as a growth plane, the contribution of quantum-confined Stark effect can be largely decreased.

Similarly about any electronic element, polarization is generated in a crystal growing direction in a channel having a semiconductor-stacked structure based on the growth of its c plane. Thus, even when no gate voltage is applied thereto, a two-dimensional electron gas layer is generated. As a result, the element becomes a transistor that can attain a normally-on-operation. However, a nonpolar plane or semi-polar plane is used to produce a high-electron-mobility transistor, a piezoelectric field based on polarization is not generated in its channel region. Thus, in the state that no gate voltage is applied thereto, the generation of a two-dimensional electron gas layer is restrained to make it possible to produce a high-electron-mobility transistor that can attain a normally-off-operation. An improvement in the electron mobility can also be expected.

Such nonpolar-plane or semi-polar-plane used semiconductor elements are classified into elements produced by growing a GaN semiconductor layer structure having a nonpolar plane or semi-polar plane epitaxially onto a substrate of nonpolar or semi-polar GaN, such as m-plane GaN; and elements produced by growing a GaN semiconductor layer structure having a nonpolar plane or semi-polar plane hetero-epitaxially onto a different-type substrate, such as a sapphire substrate or a Si substrate. According to the crystal growth onto the different-type substrate, good crystallinity can be obtained about an m-plane GaN semiconductor layer structure on an m-plane sapphire substrate, an m-plane GaN semiconductor layer structure on an a-plane sapphire substrate, and other structures.

Usually, GaN substrates are expensive; thus, it is difficult to prepare a substrate having a large diameter. It is therefore desired to produce a GaN semiconductor layer structure on an inexpensive substrate that can be made into a large diameter, such as a sapphire substrate or a Si substrate. When a substrate is made into a large diameter, costs are decreased; thus, in the production of GaN semiconductor elements, effective are semiconductor-stacked substrates in each of which a GaN semiconductor layer structure is formed on a different-type substrate having a large-diameter.

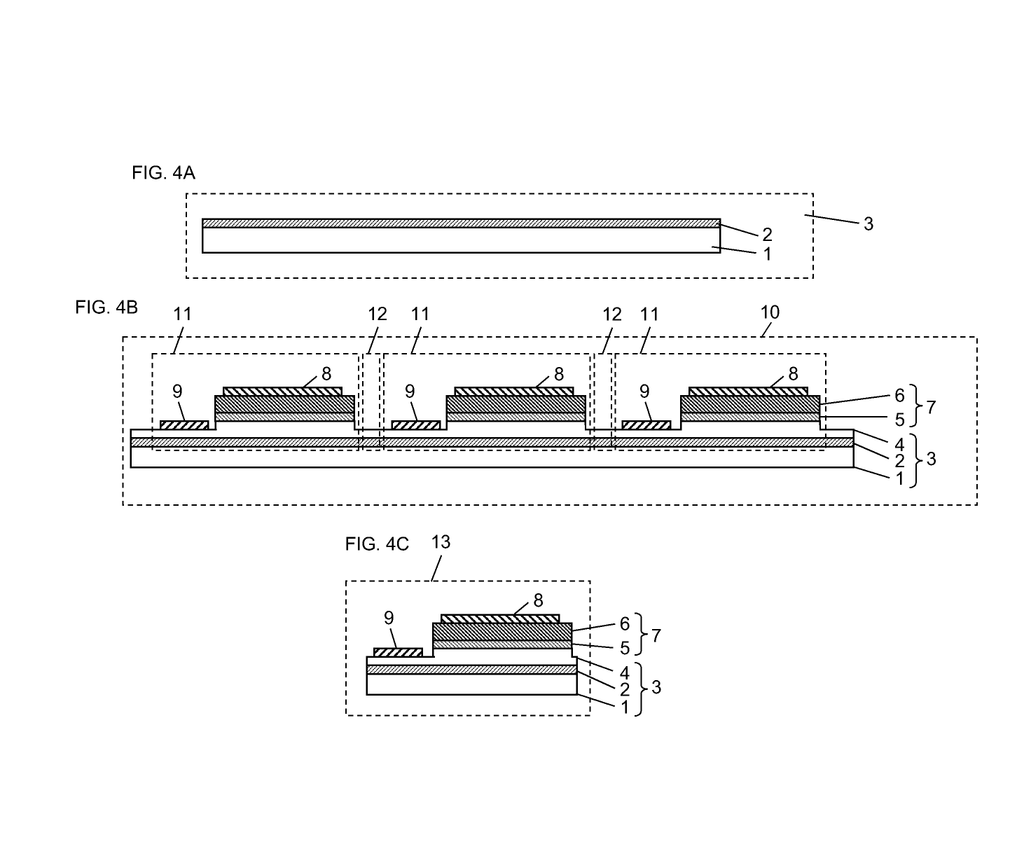

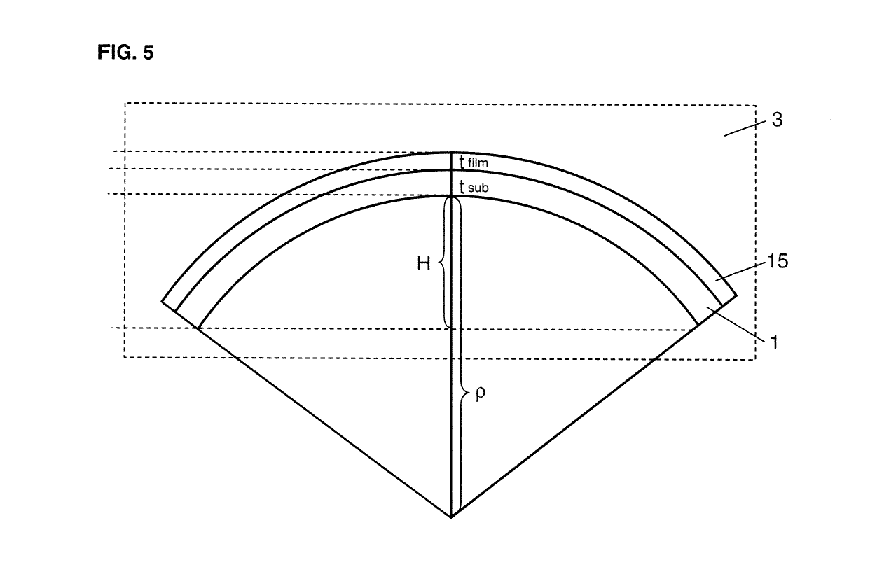

FIGS. 4A, 4B and 4C illustrate a different-species-semiconductor-stacked substrate, and a semiconductor-chip-formed semiconductor-stacked substrate produced by forming light-emitting diode elements on the semiconductor-stacked substrate.

FIG. 4A is a cross-sectional view illustrating the semiconductor-stacked substrate; FIG. 4B, a cross-sectional view illustrating a stacked structure wherein the light-emitting diode elements are formed on the semiconductor-stacked substrate; and FIG. 4C, a cross-sectional view illustrating a stacked structure having one out of semiconductor chips produced by working the light-emitting-diode-element-formed semiconductor-stacked substrate illustrated in FIG. 4B.

In each of the cross-sectional views drawn in FIGS. 4A, 4B and 4C, prepared is semiconductor-stacked substrate 3 wherein buffer layer 2 made of, for example, an m-plane GaN is stacked onto substrate 1 made of, for example, an m-plane sapphire substrate. On a principal surface thereof is formed semiconductor-stacked structure 7 wherein n-type conductive layer 4 made of GaN, active layer 5 made of a quantum well including InGaN and GaN, and p-type conductive layer 6 made of GaN are stacked onto each other. Semiconductor-stacked structure 7 is a stacked structure obtained by m-plane growth method. P-type anode electrode layer 8 is formed on p-type conductive layer 6. P-type conductive layer 6, active layer 5 and n-type conductive layer 4 are partially removed to make n-type conductive layer 4 naked. On a principal surface of naked n-type conductive layer 4 is formed n-type cathode electrode layer 9. Semiconductor wafer 10 in FIG. 4B has a region where semiconductor elements 11 are formed, and a region where scribe lines 12 are formed. By subjecting the scribe-line-12 region to dicing process, the semiconductor wafer is divided to produce semiconductor chips 13 in FIG. 4C.

The semiconductor-stacked substrate, the semiconductor wafer, and the semiconductor chip illustrated in FIGS. 4A, 4B and 4C, respectively, are each drawn into a simplified and flat form. However, the members are actually deformed. This is caused by, for example, thermal stress, or strain stress generated by a difference in material between the substrate and the semiconductor layer stacked thereon. For example, when the semiconductor layer is formed by crystal growth at high temperature and then the temperature of the resultant is returned to normal temperature, stress is generated in its individual layers so that the layers are deformed. FIG. 5 is a cross-sectional view illustrating the semiconductor-stacked substrate, and illustrates a state that semiconductor-stacked substrate 3 formed by stacking semiconductor layer 15 on substrate 1, which includes different-species-materials, is deformed. Substrate 3 is, for example, a substrate wherein a c-plane GaN semiconductor layer is formed onto a c-plane sapphire substrate by crystal growth. It is already understood that the thickness t_{sub} of substrate 1 and the thickness t_{film} of semiconductor layer 15 are strongly related to the deformation amount H, and the curvature radius ρ (of substrate 1) (see, for example, Patent Literature 3). Semiconductor layer 15 is buffer layer 2, or a layer wherein buffer layer 2 is combined with semiconductor-stacked structure 7.

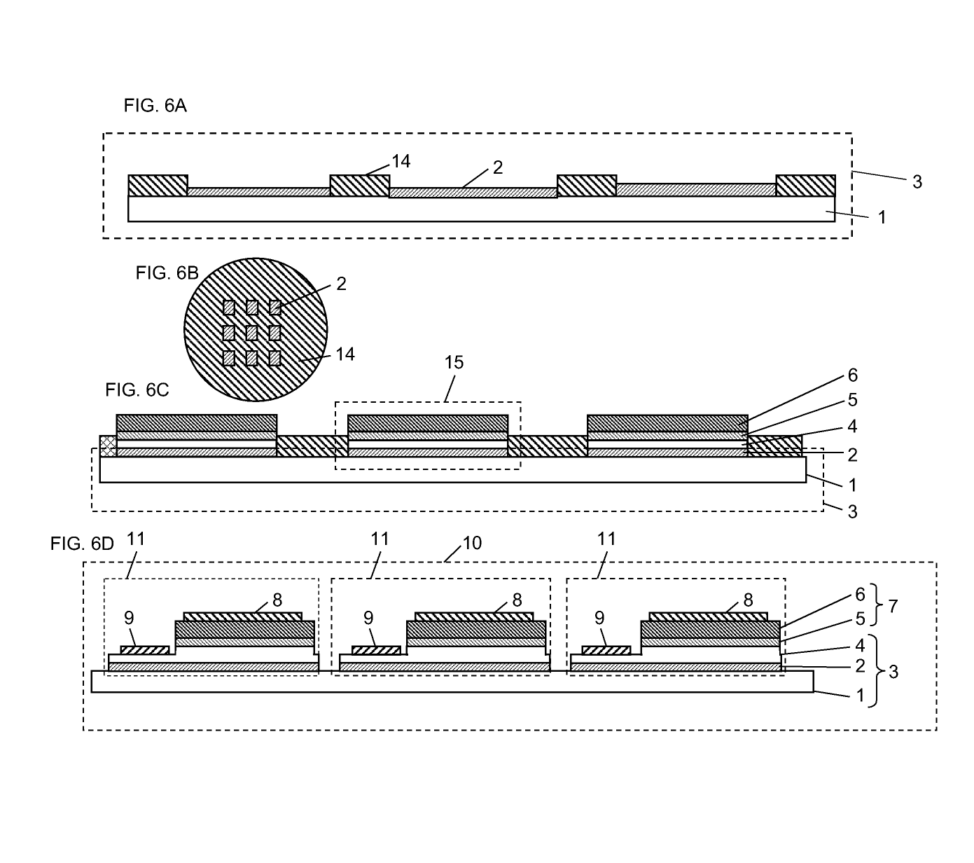

The method of producing semiconductor elements onto a different-species substrate is the most popular method. A semiconductor element producing method attained by advancing the popular method is illustrated in FIGS. 6A, 6B, 6C, and 6D. As illustrated in FIGS. 6A and 6B, a pattern based on mask 14 made of, for example, a SiO₂ film is formed on substrate 1, and buffer layer 2 is selectively formed thereon by crystal growth to produce semiconductor-stacked substrate 3. As illustrated in FIG. 6C, furthermore, a crystal is selectively grown onto buffer layer 2 to form semiconductor layer 15. As illustrated in FIG. 6D, semiconductor layer 15 is used to form semiconductor elements 11. It is stated that the use of this structure makes it possible to decrease cracks of the semiconductor layer that are based on a deformation of the substrate caused by a difference in thermal expansion coefficient between the substrate and the stacked semiconductor layer (see, for example, Patent Literatures 4 and 5).

However, the semiconductor-stacked substrate illustrated in FIGS. 4A, 4B and 4C has a problem that with an increase in the diameter of the substrate, the deformation amount caused by the thermal expansion coefficient difference is increased so that the substrate is not easily worked in subsequent steps. In particular, a sapphire substrate is hard and is difficult to work; thus, a countermeasure of making the substrate thicker to decrease the deformation is not a sufficient measure.

In general, when the deformation amount of a substrate increases, the deformation amount exceeds the limit of the focal depth in a light-exposure step to cause a problem of a pattern distortion of the resist pattern. As a result, focusing becomes difficult in a wide area. Thus, the light-exposed area attained by performing light-exposure one time is made small, and divided areas are exposed to the light. Thus, the throughput is deteriorated. A wafer formed by forming a GaN semiconductor layer onto an ordinary 2-inch sapphire substrate by crystal growth has a deformation amount of about 30 μm. The focal depth for forming a pattern having a line width of about 1 μm by use of an ordinary stepper is ±1 μm or less. In a case where the diameter of the substrate is increased to 4 inches or 6 inches, the deformation amount approaches 200 μm when the thickness of the substrate is set to about 1 mm. Thus, the present inventors have paid attention to a matter that in an increase in the diameter of a substrate, a problem of the deformation amount of the substrate becomes serious.

In a polishing step of polishing the rear surface of the substrate to make the substrate thin, its portion deformed to be projected is first polished, so that the polish amount becomes too large in scattering. Thus, when the deformation amount is as large as, for example, 200 μm, the scattering is also about 200 μm.

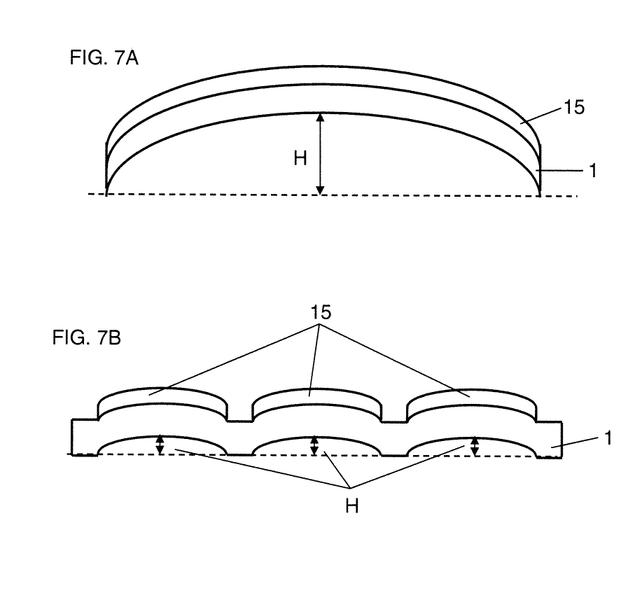

FIG. 7A is a cross-sectional view of a semiconductor-stacked substrate, and illustrates a deformation of substrate 1 when semiconductor layer 15 is formed on the whole of the front surface of substrate 1. FIG. 7B is a cross-sectional view of a semiconductor-stacked substrate, and illustrates a deformation of substrate 1 when semiconductor layer 15 is selectively grown onto substrate 1. The curvature radius ρ is generally determined in accordance with respective material parameters and the respective thicknesses of substrate 1 and semiconductor layer 15; thus, when same semiconductor layers 15 are formed on substrates 1, respectively, the curvature radii of the two are substantially equal to each other. Accordingly, about the semiconductor-stacked substrate illustrated in FIG. 7B, stress is relieved in regions thereof where semiconductor layer 15 is not partially formed, so that the deformation amount H of the whole of substrate 1 becomes small.

As described above, the semiconductor elements illustrated in FIGS. 6A, 6B, 6C and 6D have an advantageous effect for decreasing the deformation amount H of the whole of the substrate. However, no consideration is made about a matter that when a semiconductor film having a nonpolar plane or a semi-polar plane is grown, the thermal expansion coefficient or stress is varied along crystal axes in the plane. Thus, the deformation amount becomes uneven in the plane of the substrate so that the whole of the substrate is distorted.

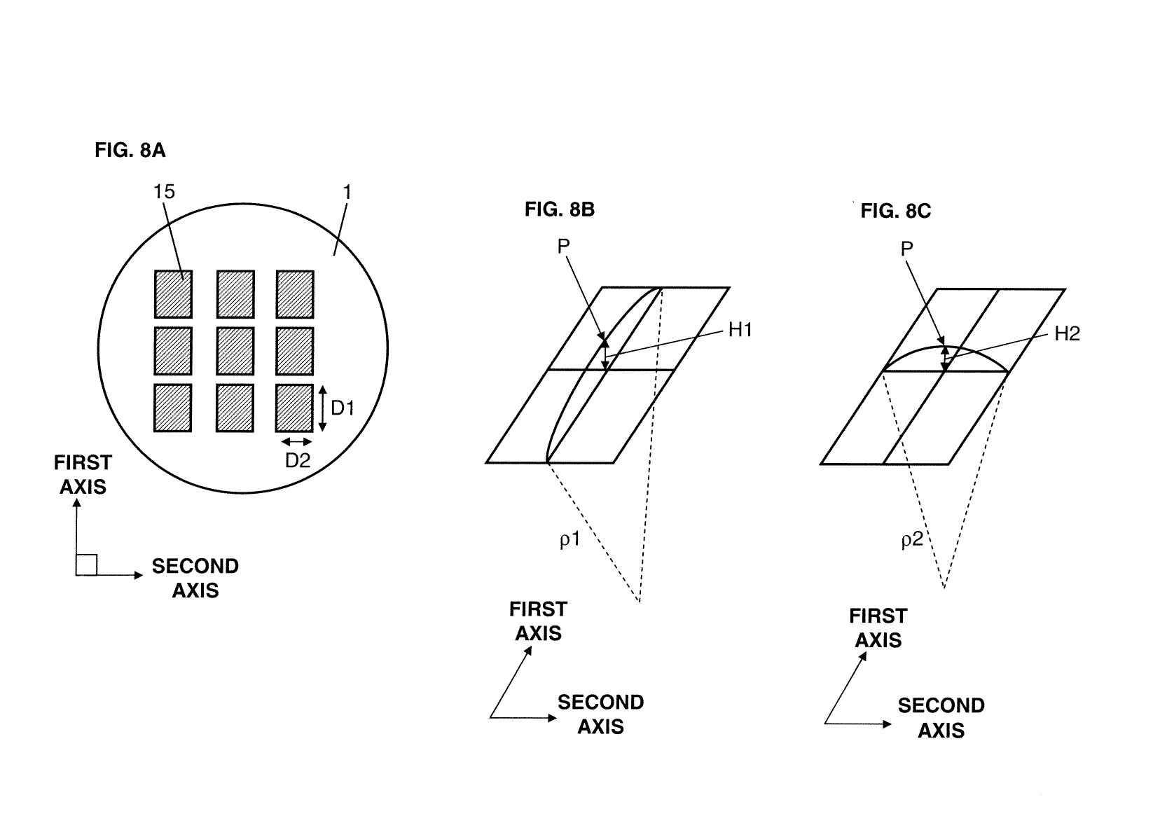

FIG. 8A is a view illustrating a principal surface of a semiconductor-stacked substrate. The illustrated semiconductor-stacked substrate is a semiconductor-stacked substrate wherein semiconductor layer 15 is selectively grown on the principal surface of substrate 1. The shape of each of sections of the semiconductor layer is a rectangle having two axes orthogonal to each other in the principal surface and having a length D1 along first one of the axes and a length D2 along second one of the axes. The lengths D1 and D2 may be different from each other. When the sections of semiconductor layer 15 each have a difference in thermal expansion coefficient or strain between in the first axis direction and the second axis direction, this semiconductor-stacked substrate comes, after the formation of layer 15, to have different deformation amounts H1 and H2 on the basis of the curvature radii ρ1 and ρ2 different from each other between in the first and second axis directions. In short, the curvature radii ρ1 and ρ2 may be different from each other. FIGS. 8B and 8C are each a schematic view illustrating the shape of the semiconductor layer section of the substrate surface. The view is a view obtained by viewing the surface obliquely from above. H1 and ρ1 respectively represent the deformation amount and the curvature radius of a cross section parallel to the first axis passing through a point P where the deformation amount of the rectangle is largest; and H2 and ρ2 respectively represent the deformation amount and the curvature radius of a cross section parallel to the second axis passing through the point P.

An example of a case where a semiconductor-stacked substrate has, in a plane thereof, anisotropy in thermal expansion coefficient is a case where a nonpolar m-plane GaN semiconductor layer is grown onto a principal surface of a sapphire substrate.

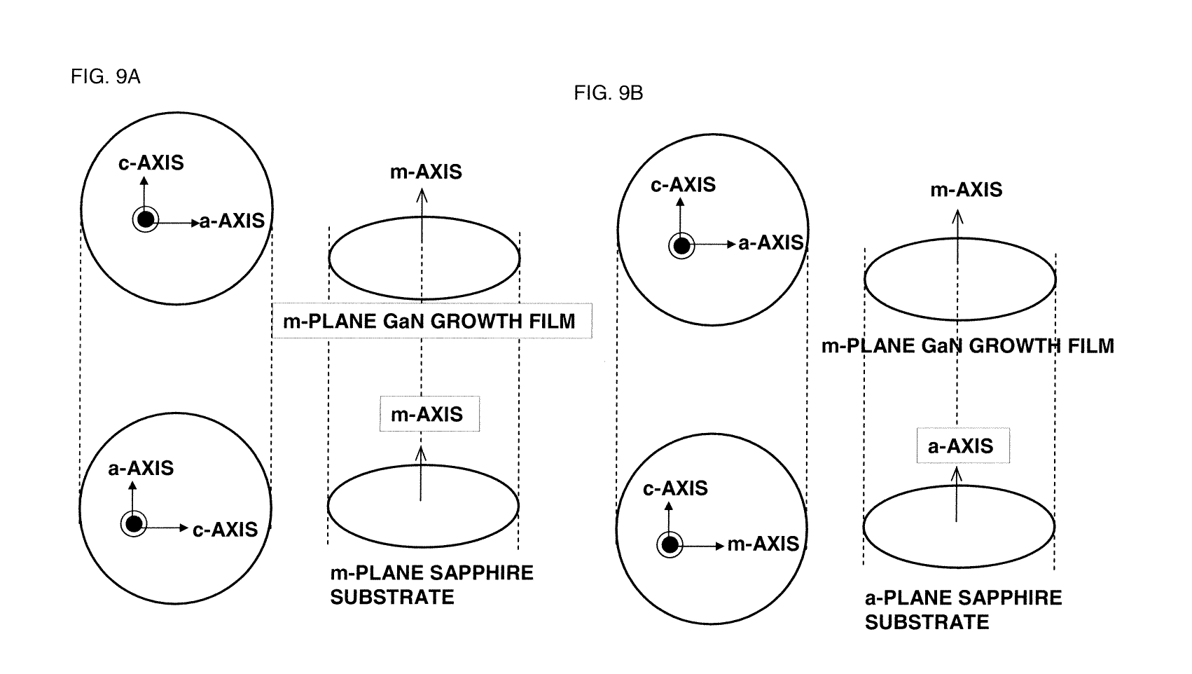

As illustrated in FIG. 9A, a principal plane of an m-plane sapphire substrate has a sapphire a-axis and a sapphire c-axis orthogonal to each other. An m-plane GaN semiconductor layer is formed by crystal growth in such a manner that the c-axis of the semiconductor layer is arranged along the a-axis of the sapphire substrate and the a-axis of the semiconductor layer is arranged along the c-axis of the sapphire substrate. Alternatively, as illustrated in FIG. 9B, a principal plane of an a-plane sapphire substrate has a sapphire c-axis and a sapphire maxis orthogonal to each other. An m-plane GaN semiconductor layer is formed by crystal growth in such a manner that the c-axis of the semiconductor layer is arranged along the c-axis of the sapphire substrate and the a-axis of the semiconductor layer is arranged along the maxis of the sapphire substrate.

In the case of the GaN semiconductor layer of the c-plane growth method, the crystal structure thereof is a point-rotationally symmetric structure. It is therefore desired that the shape of each of the semiconductor film sections has a point-rotationally symmetric structure, such as a square, a circle, or a hexagon. However, when a difference is observed in thermal expansion coefficient or strain in two axes parallel to the growth plane and orthogonal to each other as seen in an m-plane GaN semiconductor layer, the formation of the film to have the same structure causes anisotropy in deformation amount so that the deformation amount in the first axis direction is made different from that in the second axis direction.

When the deformation amounts are different, it is necessary to adjust the steps to be matched with a larger deformation amount out of the respective deformation amounts in the axis directions. Thus, restrictions onto the polishing step and light-exposure step are increased so that the semiconductor-stacked substrate is declined in precision and is increased in costs. In order to make the area of the semiconductor layer effective for the substrate area into a maximum level, it is necessary to make the deformation amounts in the two axis directions equivalent to each other.

In a method for forming a single selectively-grown semiconductor film section onto each diode or each transistor, the area of the mask region for separating the individual semiconductor layers from each other becomes larger than the area of the semiconductor film, so that costs increase.

In an edge region of each semiconductor film section having a nonpolar plane or semi-polar plane formed by selective growth, various planes make their appearance along the shape of the mask pattern, such as the a-axis direction, and the c-axis direction. Thus, when this film is compared with the film of the case of c-plane growth method, the atomic composition or the film thickness thereof becomes uneven to cause a problem that the control of properties of the element, such as the wavelength thereof, becomes difficult. When the edge region is etched to be removed, a region where the film thickness or the composition is instable can be removed. However, a loss of the area is caused so that costs increase.

The inventors have made eager researches to provide a semiconductor-stacked substrate which can be reduced in deformation amount, and can further give an even in-plane deformation amount, undergo a light-exposure step to give a good throughput, undergo a polishing step to give a small polish scattering, give an effectively usable substrate area, and easily make the substrate-diameter large; and a semiconductor chip having the same advantages.

According to the embodiments of the present disclosure, a region where no semiconductor layer is stacked on a substrate is formed, thereby making it possible to form a region where stress to the substrate is relieved. Thus, the deformation amount of the whole of the substrate can be decreased. By specifying, at this time, the size of each of the semiconductor layers to be formed, the deformation amount of the substrate can be made even in the plane thereof.

In this way, restrictions in the light-exposure step are relieved so that a fine mask pattern can be produced with a good throughput. In the polishing, the whole of the substrate can be evenly polished.

Furthermore, according to the embodiments of the present disclosure, the deformation amount of the substrate can be made even in the plane thereof to be matched with the focal depth in the light-exposure step, or with an allowable value, for polish thickness scattering, allowed in the polishing step. Thus, the area of the semiconductor layer for producing elements can be set into a maximum level so that costs can be decreased.

According to the embodiments of the present disclosure, the selectively grown area can be set to a maximum area where an allowable deformation is generated to reduce the proportion of the area of a crystal-quality-poor portion of the periphery of each of the semiconductor layers formed by selective growth to the total area of the semiconductor layer section. As a result, the substrate area can be effectively used to make it possible to produce chips.

As described above, the embodiments of the present disclosure solve problems caused by a deformation of a substrate in the case of an increase in the diameter of the substrate to produce an advantageous effect for decreasing costs.

Hereinafter, with reference to the drawings, exemplary embodiments of the present invention will be described.

### Exemplary Embodiment 1

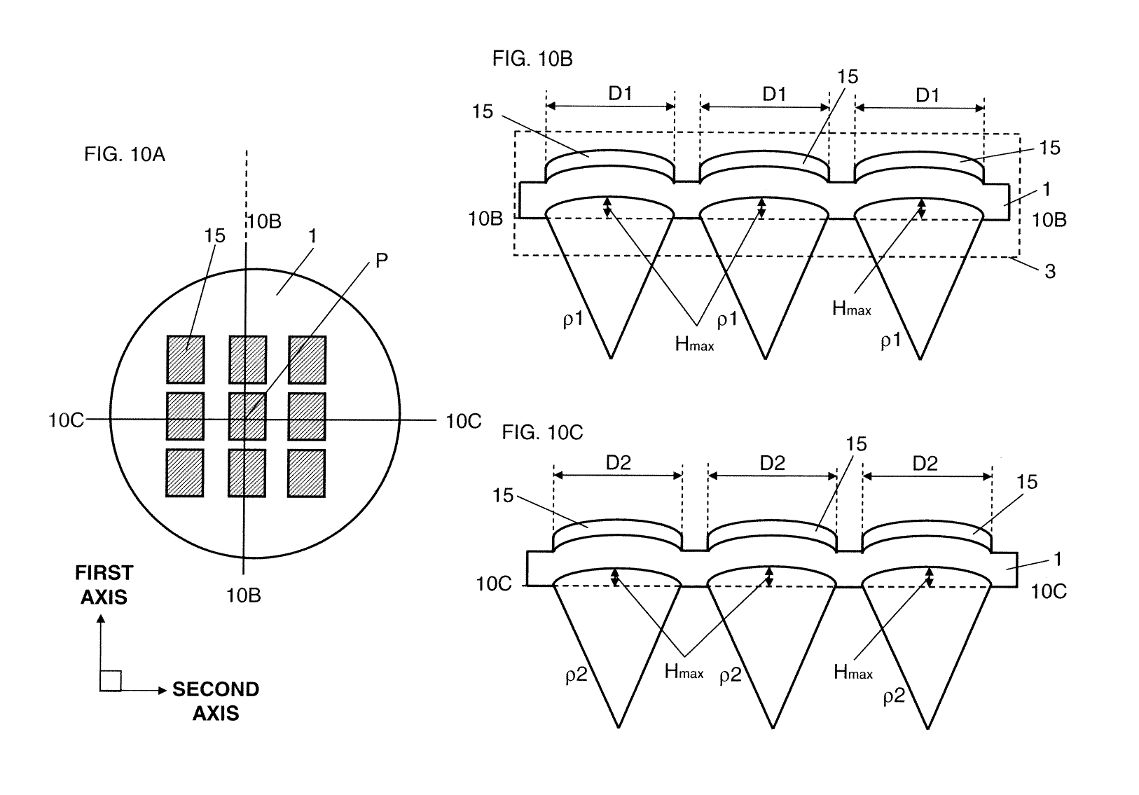

FIG. 10A is a view illustrating a principal surface of a semiconductor-stacked substrate of exemplary embodiment 1 according to the present invention. FIGS. 10B and 10C are cross-sectional views of the semiconductor-stacked substrate. In FIGS. 10A, 10B and 10C, the same reference numbers are attached, to the same constituents as in FIGS. 4A, 4B and 4C and FIGS. 6A, 6B and 6C.

As illustrated in FIG. 10A, the semiconductor-stacked substrate of the present exemplary embodiment has a structure wherein a section or sections of semiconductor layer 15 made of an m-plane GaN, are formed on substrate 1 made of an m-plane sapphire substrate by crystal growth. When the section or each of the sections of semiconductor layer 15 is viewed from the principal surface side of substrate 1, the section of semiconductor layer 15 has a rectangular shape. One side thereof is parallel to a first axis, and a different side thereof is a second axis, which is orthogonal to the first axis. The first axis direction and the second axis direction are within a plane along the principal surface of the semiconductor-stacked substrate. For example, in the semiconductor-stacked substrate wherein an m-plane GaN semiconductor layer has been formed onto an m-plane sapphire by crystal growth, the first axis direction is the c-axis direction of the m-plane GaN semiconductor layer, and is the a-axis direction of the m-plane sapphire substrate. The second axis direction is the a-axis direction of the m-plane GaN semiconductor layer, and is the c-axis direction of the m-plane sapphire substrate. In the present exemplary embodiment, each of the sections of semiconductor layer 15 has anisotropy in thermal expansion coefficient, so that the exemplary embodiment is characterized by being different in thermal expansion coefficient between in the first axis direction and the second axis direction. Distortion stress generated between the semiconductor layer 15 and the substrate 1 also has anisotropy therebetween, so that the stress in the first axis direction is different from that in the second axis direction. In other words, distortion stress generated between the semiconductor layer 15 and the substrate 1 also has anisotropy therebetween, so that a difference is generated between in the first axis direction and the second axis direction.

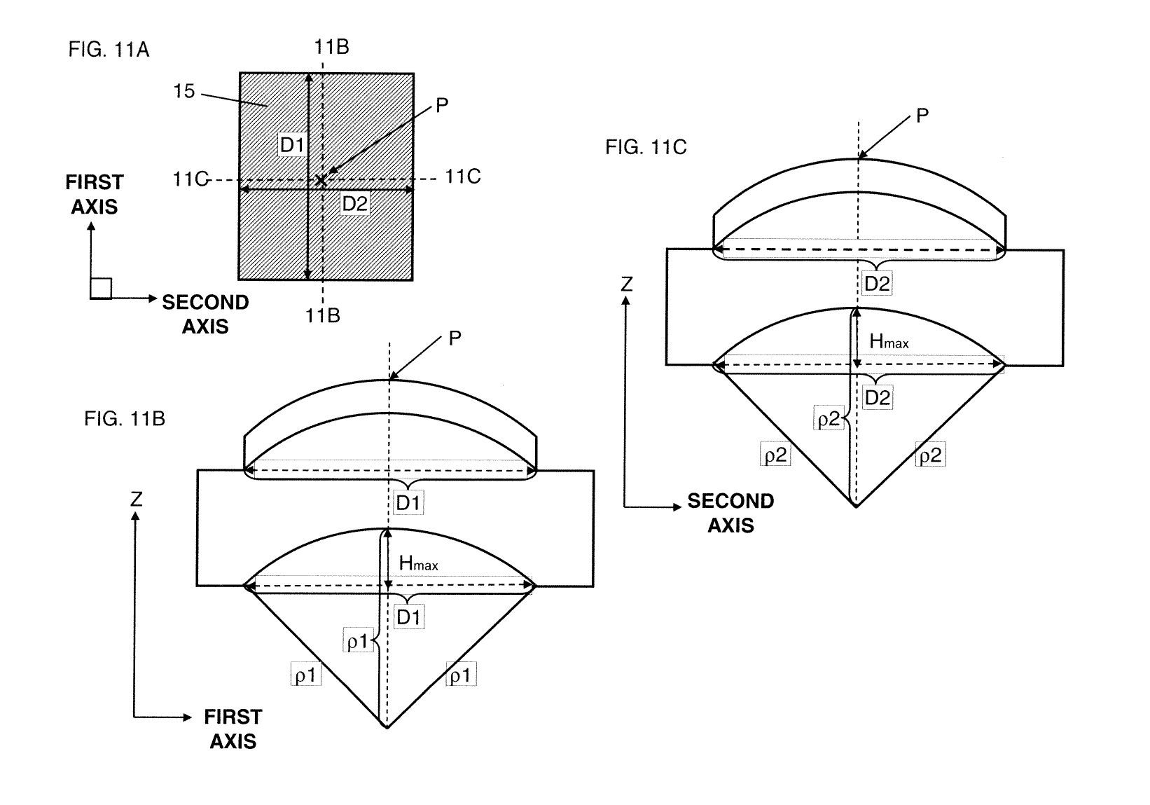

FIG. 11A is a view illustrating the principal surface of one of the sections of semiconductor layers 15. FIGS. 11B and 11C are cross-sectional views of the semiconductor-stacked substrate.

As described above, the section of semiconductor layer 15 has a rectangular shape in the top view. In the section of semiconductor layer 15, point P which is largest in deformation may or may not be the center of the rectangle. The deformation amount at point P is represented by Hₘₐₓ. D1 represents the length of a side in the first axis direction of the rectangle, this side passing through point P. D2 represents the length of a side in the second axis direction of the rectangle, this side also passing through point P. Since the section of semiconductor layer 15 has the rectangular shape, the lengths D1 and D2 are different from each other.

FIG. 11B is a cross-sectional view taken along the line 11B-11B passing through point P in FIG. 11A. FIG. 11C is a cross-sectional view taken along the line 11C-11C included in FIG. 11A. In FIG. 11B, ρ1 represents the curvature radius of the semiconductor-stacked substrate at point P along the cross-section 11B-11B. In FIG. 11C, ρ2 represents the curvature radius of the semiconductor-stacked substrate at point P along the cross-section 11C-11C.

The line 10B-10B included in FIG. 10A is a line traversing the semiconductor-stacked substrate along the first axis direction. The line 10C-10C included in FIG. 10A is a line traversing the semiconductor-stacked substrate along the second axis direction. FIG. 10B is a cross-sectional view taken along the line 10B-10B included in FIG. 10A, and FIG. 10C is a cross-sectional view taken along the line 10C-10C included in FIG. 10A. Similarly, ρ1 and ρ2 are each a curvature radius of the semiconductor-stacked substrate.

When a deformation is generated by the case of stacking, in such a way, two materials different from each other in thermal expansion coefficient or any other physical property constant onto each other, the internal stress-σ (T) generated therein depends on the temperature, and is represented by the following mathematical formula 6:

$$\begin{matrix}Mathematical formula 6 & \\ σ ( T ) = \frac{{E}_{sub} {t}_{sub}^{2}}{6 {ρ}_{T} {t}_{film} ( 1 - {v}_{sub} )} & [ Math . 6 ]\end{matrix}$$

where E_{sub}: the Young's modulus of a substrate;

t_{sub} and t_{film}: film thickness of the substrate, and that of a semiconductor layer, respectively;

ρ_{T}, the curvature radius at the temperature T;

ν_{sub}: the Poisson's ratio of the substrate.

When the semiconductor layer is formed on the substrate at a temperature T_{g} by crystal growth and then the temperature is turned to a normal temperature Tₐ, thermal stress generated in this stacked structure is the variation of the internal stress at the temperature Tₐ relative to that at the temperature T_{g}, and is represented by the following mathematical formula 7:

[Math. 7]

Δσ=(σ(T_{g})−σ(Tₐ))(T_{g}−Tₐ) Mathematical formula 7

The thermal stress generated in this semiconductor layer is represented by the following mathematical formula 8, using the thermal expansion coefficient α_{sub} of the substrate, the thermal expansion coefficient α_{film} of the semiconductor layer, and the Young's modulus E_{film} and the Poisson's ratio ν_{film} of the semiconductor layer:

$$\begin{matrix}Mathematical formula 8 & \\ σ = \frac{{E}_{film} ( {α}_{film} - {α}_{sub} )}{1 - {v}_{film}} ( {T}_{a} - {T}_{g} ) & [ Math . 8 ]\end{matrix}$$

For example, when the thermal stress is dominant, the following mathematical formula 9 is satisfied so that about the curvature radius ρ at normal temperature, the following relational mathematical formula is derived:

$$\begin{matrix} Mathematical formula 9 & \\ \begin{matrix}\frac{{E}_{film} ( {α}_{film} - {α}_{sub} )}{1 - {v}_{film}} ( {T}_{a} - {T}_{g} ) = Δ σ \\ = ( σ ( {T}_{g} ) - σ ( {T}_{a} ) ) ( {T}_{g} - {T}_{a} ) \\ = - σ ( {T}_{a} ) ( {T}_{g} - {T}_{a} ) \\ = \frac{{E}_{sub} {t}_{sub}^{2}}{6 {ρ}_{{T}_{a}} {t}_{film} ( 1 - {v}_{sub} )} ( {T}_{a} - {T}_{g} )\end{matrix} & [ Math . 9 ] \\ Mathematical formula 10 & \\ ρ = \frac{{E}_{sub} {t}_{sub}^{2} ( 1 - {v}_{film} )}{6 {E}_{film} {t}_{film} ( {α}_{film} - {α}_{sub} ) ( 1 - {v}_{sub} )} & [ Math . 10 ]\end{matrix}$$

Separately, among the deformation amount H, the curvature radius ρ and the length D of each section of the semiconductor layer, a relation of the following mathematical formula 11 is satisfied:

$$\begin{matrix}Mathematical formula 11 & \\ H = \frac{{D}^{2}}{8 ρ} & [ Math . 11 ]\end{matrix}$$

This mathematical formula 11 is derived as described below. When the Pythagorean theorem is applied to the cross-sectional view of FIG. 11B, the following is obtained:

[Math. 12]

ρ1²=(½D1)²+(ρ1−Hₘₐₓ)² Mathematical formula 12

[Math. 13]

0=¼D1²−2ρ1Hₘₐₓ+Hₘₐₓ² Mathematical formula 13

[Math. 14]

2ρ1Hₘₐₓ=¼(D1²+4Hₘₐₓ²) Mathematical formula 14

Because of D>>Hₘₐₓ, the following mathematical formula 15 is derived.

[Math. 15]

2ρ1Hₘₐₓ=¼D1² Mathematical formula 15

Then, the following mathematical formula 16 is derived by modifying the mathematical formula 15:

$$\begin{matrix}Mathematical formula 16 & \\ {H}_{max} = \frac{D {1}^{2}}{8 ρ 1} & [ Math . 16 ]\end{matrix}$$

The mathematical formula 16 represents a relationship among the deformation amount Hₘₐₓ, the curvature radius ρ1, and the semiconductor layer length D1 in the first axis direction. Similarly, a relationship among the deformation amount Hₘₐₓ, the curvature radius ρ2, and the semiconductor layer length D2 in the second axis direction is represented by the following mathematical formula 17:

$$\begin{matrix}Mathematical formula 17 & \\ {H}_{max} = \frac{D {2}^{2}}{8 ρ 2} & [ Math . 17 ]\end{matrix}$$

Thus, when the aspect ratio between the length and the breadth of each of the semiconductor layers is set to have a relationship represented by the following mathematical formula 18 relative to the curvature radius ρ1 in the first axis direction and that ρ2 in the second axis direction, the deformation amount H1 in the first axis direction is equivalent to that H2 in the second axis direction.

$$\begin{matrix}Mathematical formula 18 & \\ \frac{D 1}{D 2} = \frac{\sqrt{ρ 1}}{\sqrt{ρ 2}} & [ Math . 18 ]\end{matrix}$$

In this case, the deformation amount H1 in the first axis direction is assumed to be equal to the deformation amount H2 in the second axis direction.

It is practically necessary to adjust the yield to 80% or more, and the range of allowance for a design value of the length D1 is ±20%.

In light of the mathematical formula 18, the area defined by the formula D1×D2 of the rectangle of the semiconductor layer is represented by the following mathematical formula 19:

$$\begin{matrix}Mathematical formula 19 & \\ D 1 \times D 2 = D {2}^{2} \frac{\sqrt{ρ 1}}{\sqrt{ρ 2}} & [ Math . 19 ]\end{matrix}$$

Accordingly, the following mathematical formula 20 is satisfied, considering that the range of allowance for the area defined by the formula D1×D2 of the rectangle of the semiconductor layer is within ±20%.

$$\begin{matrix}Mathematical formula 20 & \\ 0.8 D 1 \times D 2 \leq D {2}^{2} \frac{\sqrt{ρ 1}}{\sqrt{ρ 2}} \leq 1. 2 D 1 \times D 2 & [ Math . 20 ]\end{matrix}$$

The mathematical formula 20 is simplified to be turned to the mathematical formula 1.

$$\begin{matrix}Mathematical formula 1 & \\ 0. 8 D 1 \leq D 2 \frac{\sqrt{ρ 1}}{\sqrt{ρ 2}} \leq 1. 2 D 1 & [ Math . 1 ]\end{matrix}$$

Thus, when the size of the rectangle of the semiconductor layer is determined to satisfy the mathematical formula 1, the semiconductor-stacked substrate can be obtained wherein the maximum value of the deformation amount of the semiconductor layer is even, for practical use, within the plane of the substrate.

In the present exemplary embodiment, about each of the semiconductor layers of the semiconductor-stacked substrate, the maximum value of the deformation amount in the first axis direction can be made substantially equal to the maximum value of the deformation amount in the second axis direction, so that over the whole of the semiconductor-stacked substrate, substantially even become the respective heights of the vicinities of central regions of the individual semiconductor layers, which give the topmost or bottommost planes of the substrate. Substantially even also become the respective heights of the vicinities of individual regions of the individual semiconductor layers, which give the bottommost planes or topmost planes of the substrate. Thus, the deformation amount of the whole of the semiconductor-stacked substrate is small, and further the whole of the substrate is in a flat form.

Usually, in a polishing step, from the utmost projected portion of the rear surface of a substrate, the substrate is first polished. In the exemplary embodiment, however, the substrate rear surface projects evenly over the whole of the substrate, not to easily generate any spot where the substrate is extremely thickly or thinly finished. Thus, the thickness thereof is easily controlled. The deformation amount of the whole of the substrate is small; thus, in a case where in the light-exposure step, each of the semiconductor layers is set into a size permitting the deformation amount of the layer to be kept within the focal depth of the light-exposure device, the sections of semiconductor layer 15 can be simultaneously exposed to light over the whole of the substrate surface. At this time, the region where the sections of semiconductor layer 15 are not stacked (region where the pattern is formed by mask 14) can be decreased into a minimum level so that the area of the semiconductor layers can be set into a maximum level. Thus, the throughput can be improved, and the number of picked-up chips can be increased. Moreover, even when the deformation amount of the whole of the substrate is larger than the focal depth and each of its semiconductor layers is exposed to light in the unit of each of divided areas of the section, the distance between the surface to be exposed to the light and the light source is even; thus, each focusing is easily attained. This matter makes it possible to decrease the region where the semiconductor layers are not stacked into a minimum level to set the area of the semiconductor layers into a maximum level. Thus, the number of picked-up chips can be increased.

In an example of the present exemplary embodiment, it is possible to: grow a desired semiconductor layer onto the whole of a surface of a desired substrate; measure the respective deformation amounts of two orthogonal axes, between in which a difference is generated in thermal expansion coefficient, along respective cross sections passing through the center of the substrate; obtain the respective curvature radii; and then determine the ratio between the respective side-lengths of each of the semiconductor layers on the supposition that the curvature radius of the semiconductor film grown on the entire surface is equivalent to that of the semiconductor layers formed by crystal growth onto openings made by patterning.

The use of this method makes it possible to set an optimal size ratio even in the case of not making precise measurements about physical property constants of the substrate or the semiconductor layers, such as the thermal expansion coefficient, the Young's modulus, the Poisson's ratio, and the distortion amount thereof. The use also makes it possible to set an optimal size ratio precisely even in the case of a structure wherein semiconductor layers different from each other in material are stacked into a multilayered form, or in a case where a semiconductor-stacked substrate is distorted so that a large effect of stress is produced. Even when the semiconductor layer is only a buffer layer, the advantageous effects are sufficiently produced. However, it is desired to design a size ratio about an object or workpiece which is in a state closer to a final form of the semiconductor-stacked substrate, this state being attained by stacking semiconductor layers including an n-type conductive layer, an active layer, and a p-type conductive layer.

In the present exemplary embodiment, as the substrate, the m-plane sapphire substrate has been described. However, the substrate may be a substrate made of a different material, such as an a-plane sapphire substrate, a silicon substrate, or a SiC substrate. As the semiconductor layer, the m-plane GaN semiconductor layer has been described. However, any film may be used as far as the film is a film having, in each of its sections, different thermal expansion coefficients between in the first axis direction and the second axis direction. Thus, the film may be a GaN based semiconductor layer represented by a general formula of AlₓGa_{y}In_{z}N wherein x+y+z=1, x≧0, y≧0, and z≧0. When m-plane GaN semiconductor layer 15 is formed onto an a-plane sapphire substrate, the first axis direction is the c-axis direction of the m-plane GaN semiconductor layer and is the c-axis direction of the m-plane sapphire substrate while the second axis direction is the a-axis direction of the m-plane GaN semiconductor layer and is the m-axis direction of the m-plane sapphire substrate.

A method for producing the present exemplary embodiment may be equivalent to a conventional method, which may be a method of forming, onto a substrate, a mask pattern made of, for example, an oxide film, and having openings each having a diameter of a size of D1 along the first axis direction, and a diameter of a size of D2 along the second axis direction; and then forming semiconductor layers onto the respective openings by crystal growth in such a selectively-forming manner that the semiconductor layers are not connected to each other on the mask pattern. If the semiconductor layers are connected to each other on the mask pattern, stress acts onto the connection regions. Thus, it is desired to prevent the generation of the connection as far as possible.

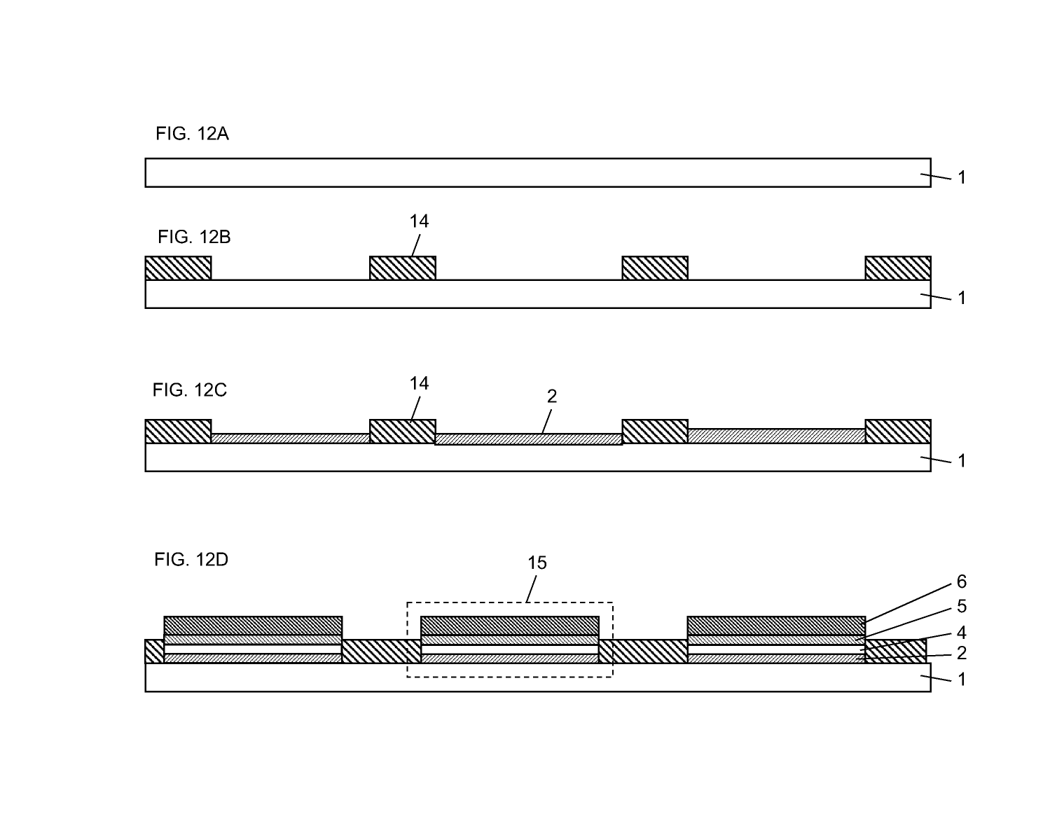

Hereinafter, with reference to FIGS. 12A, 12B, 12C and 12D, a description will be made about a specific method for producing the present exemplary embodiment. FIGS. 12A, 12B, 12C and 12D are views illustrating the method for producing the semiconductor-stacked substrate of the present exemplary embodiment.

Prepared is first substrate 1 that is a sapphire substrate for crystal growth (FIG. 12A). Next, mask 14, for crystal growth, made of an oxide film is formed on substrate 1 (FIG. 12B). Openings in mask 14 for selective growth each have, between the length and breadth, the ratio D1/D2 disclosed in the present specification. In particular, the m-plane of a GaN based semiconductor layer is large in step growth rate in the a-axis direction; thus, by rendering the a-axis direction in the plane thereof the long side direction of each of the openings in mask 14, a good crystal growth can be realized while GaN polycrystal is restrained from being deposited onto mask 14. Substrate 1 is washed with phosphoric acid, and then sufficiently washed with water. Substrate 1 is then dried. After the washing is conducted, substrate 1 is set in a reaction chamber of an MOCVD machine while the contact of substrate 1 with the air is avoided as much as possible.

The reaction chamber is connected to a gas supply device. From the gas supply chamber, various gases (such as raw material gases, carrier gases, and dopant gases) are supplied into the reaction chamber. Moreover, a gas exhaust device is connected to the reaction chamber. The reaction chamber is exhausted through the gas exhaust device (rotary pump). About crystal growth, in particular, reduced-pressure growth is performed, thereby restraining the deposition of polycrystal onto mask 14. For the m-plane growth method (of the crystal), the reduced pressure is desirably from 200 Torr to 500 Torr both inclusive. This pressure also makes it possible to restrain the incorporation of, in particular, oxygen and others. The reduced-pressure growth method is attained by controlling gas exhaust through a gas exhaust valve.

Next, substrate 1 is subjected to thermal cleaning. Specifically, hydrogen having a flow rate of 4 slm to 10 slm both inclusive and nitrogen (N₂) having a flow rate of 3 slm to 8 slm both inclusive are supplied as carrier gases; and ammonia is supplied into the reaction chamber as a Group V raw material. Simultaneously, substrate 1 is heated to 850° C. to subject the surface of substrate 1 to cleaning treatment.

Next, in the reaction chamber, a GaN based semiconductor layer is formed by crystal growth through an MOCVD process.

While raw material gases and the carrier gases are first supplied into the reaction chamber, buffer layer 2 is formed (FIG. 12C). The substrate temperature is lowered to 500° C. As the raw material gases, trimethyl gallium (TMG) or triethyl gallium (TEG) having a flow rate of 10 sccm to 40 sccm both inclusive is supplied as a Group III raw material, and ammonia having a flow rate of 4 slm to 10 slm both inclusive is supplied as a Group V raw material to grow a GaN buffer into a thickness of 30 nm.

Next, while raw material gases, an n-type dopant and the carrier gases are supplied into the reaction chamber, substrate 1 is heated to about 1100° C. to form n-type conductive layer 4 made of n-type GaN and having a thickness of 1 μm to 4 μm both inclusive. As the raw material gases, trimethyl gallium (TMG) or triethyl gallium (TEG) having a flow rate of 10 sccm to 40 sccm both inclusive is supplied as a Group III raw material, and ammonia having a flow rate of 4 slm to 10 slm both inclusive is supplied as a Group V raw material. As a raw material for supplying Si, which is the n-type dopant, silane having a flow rate of 10 sccm to 30 sccm both inclusive is supplied. As the carrier gases, hydrogen having a flow rate of 4 slm to 10 slm both inclusive and nitrogen (N₂) having a flow rate of 3 slm to 8 slm both inclusive are supplied. According to the present growth conditions, n-type conductive layer 4 made of n-type GaN is formed selectively only in the mask openings.

Next, in order to form GaN/InGaN multiquantum well active layer 5, the temperature of substrate 1 is lowered to a temperature lower than 800° C. In this cooling step, the supply of silane and TMG (or TEG) is stopped, and the supply of ammonia having a flow rate of 15 slm to 20 slm both inclusive is continued. The supply of hydrogen, out of the carrier gases, is stopped, and only nitrogen having a flow rate of 15 slm to 20 slm, as one of the carrier gases, is supplied. After the stop of the supply of hydrogen, the supply of hydrogen is not re-started until the formation of a GaN barrier layer and an InₓGa₁₋ₓN well layer (wherein 0<x<1) is completed. A purpose for stopping the supply of hydrogen in this way is that in the step of forming the InₓGa₁₋ₓN well layer (wherein 0<x<1), the amount of In taken into the layer is made large.

Substrate 1 is cooled until the temperature thereof is lowered to a temperature lower than 800° C. When the temperature is stabilized, the supply of TMG (or TEG), which is a raw material gas for Ga, is restarted at a flow rate of 4 sccm to 10 sccm both inclusive. In this way, the GaN barrier layer is formed.

Next, in the state that the temperature of substrate 1 is kept, the supply of trimethylindium (TMI) is started to form the InₓGa₁₋ₓN well layer (wherein 0<x<1). At this time, into the reaction chamber, nitrogen having a flow rate of 15 slm to 20 slm both inclusive, ammonia having a flow rate of 15 slm to 20 slm both inclusive, TMG (or TEG) having a flow rate of 4 sccm to 10 sccm both inclusive, and TMI having a flow rate of 300 sccm to 600 sccm both inclusive are supplied; and the supply of hydrogen is being stopped. Desirably, the thickness of the InₓGa₁₋ₓN well layer (wherein 0<x<1) is typically 5 nm or more. The thickness of the GaN barrier layer is preferably set to a value corresponding to the thickness of the InₓGa₁₋ₓN well layer (wherein 0<x<1). When the thickness of the InₓGa₁₋ₓN well layer (wherein 0<x<1) is, for example, 9 nm, that of the GaN barrier layer is from 15 nm to 30 nm both inclusive. Thereafter, GaN barrier layers and InₓGa₁₋ₓN well layers (wherein 0<x<1) are alternately deposited so that the respective numbers of the two-species-layers turn to 3 or more. This way gives GaN/InGaN multiquantum well active layer 5, which is to function as a light-emitting part, wherein three or more periods each including one of the GaN barrier layers and one of the InₓGa₁₋ₓN well layers (wherein 0<x<1) are stacked. The reason why the number of the periods is adjusted to three or more is that as the layer-number of the InₓGa₁₋ₓN well layers (wherein 0<x<1) is larger, an element to be obtained becomes larger in volume capable of capturing carriers contributing to recombination for light-emitting, so that the element is increased in efficiency.

After the formation of all the InₓGa₁₋ₓN well layers (wherein 0<x<1) in GaN/InGaN multiquantum well active layer 5, the supply of TMI is stopped and the supply of hydrogen is restarted. In this way, nitrogen having a flow rate of 3 slm to 8 slm both inclusive, and hydrogen having a flow rate of 4 slm to 10 slm both inclusive are supplied into the reaction chamber. Furthermore, the temperature for the growth is raised to 1000° C., and TMG (or TEG) and ammonia, which are raw material gases, and Cp2Mg (biscyclopentadienyl magnesium) as a material for Mg, which is a p-type dopant are supplied, to form p-type conductive layer 6 made of p-type GaN (FIG. 12D). However, various conditions such as the Cp2Mg supply amount, and the TMG (or TEG) supply amount are adjusted to set the concentration of Mg contained in the p-type GaN into a range preferably from 4.0×10¹⁸ cm⁻³ to 1.8×10¹⁹ cm⁻³ both inclusive, more preferably from 6.0×10¹⁸ cm⁻³ to 9×10¹⁸ cm⁻³ both inclusive.

About a method for adjusting the various conditions, it is advisable, for example, that in the state of setting the growth temperature to about 1000° C. and making the TMG (or TEG) supply amount constant, the Cp2Mg supply amount is controlled. It is advisable, for example, to supply TMG (or TEG) at a flow rate of 5 sccm to 10 sccm both inclusive, ammonia at a flow rate of 4 sccm to 10 slm both inclusive, and Cp2Mg at a flow rate of 10 sccm to 100 sccm both inclusive.

However, magnesium may be incorporated into a region from the surface of the p-type GaN to a depth of about 20 nm (the uppermost region having a thickness of 20 nm), in the p-type GaN, to give a concentration higher than 1.8×10¹⁹ cm⁻³. In this case, it is advisable to set the magnesium concentration in the region obtained by excluding the uppermost region from the p-type GaN into a range from 4.0×10¹⁸ cm⁻³ to 1.8×10¹⁹ cm⁻³, more preferably from 6.0×10¹⁸ cm⁻³ to 9.0×10¹⁸ cm⁻³. When the concentration of the p-type dopant is locally made high in the uppermost region of the GaN layer, which a p-side electrode contacts, the contact resistance can be lowered into a minimum level. Such an impurity-doping also produces an advantage that the semiconductor-stacked substrate is decreased in in-plane scattering in current-voltage property so that the chips can be decreased in scattering in driving voltage.

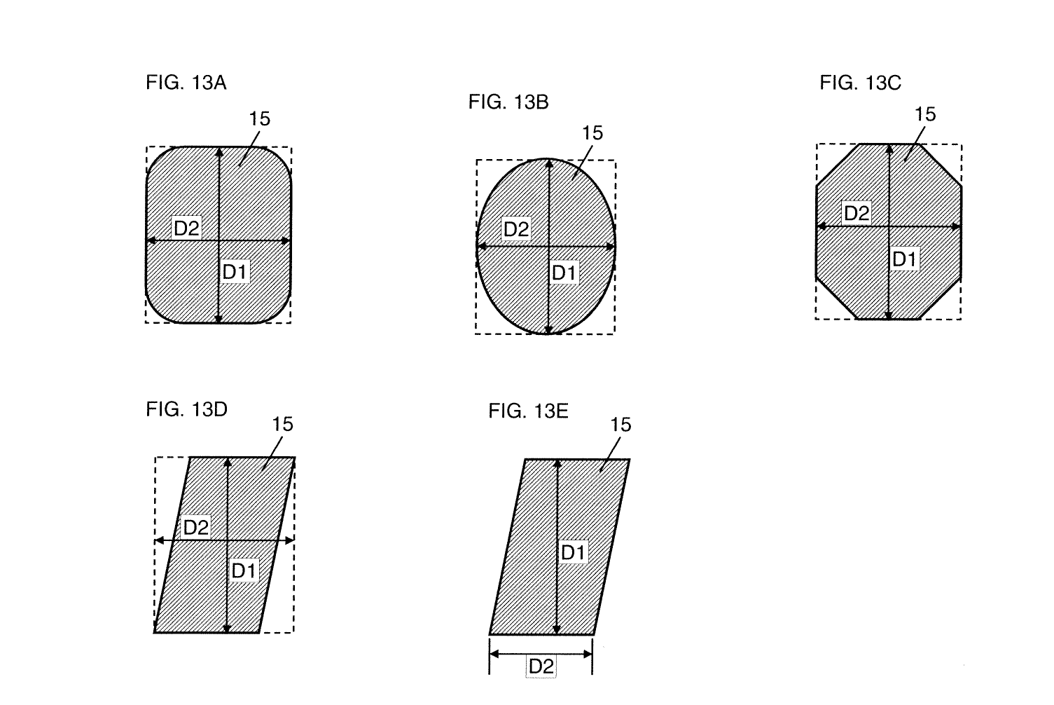

When the surface of the semiconductor-stacked substrate is viewed from above, the shape of each of the semiconductor layers is preferably rectangular. However, the shape may be deformed as far as the deformed shape is held into a rectangle having the determined size ratio to contact this rectangle. For example, the following may be selected: a substantial rectangle, an ellipse, a polygon, and a parallelogram as illustrated in FIGS. 13A, 13B, 13C, and 13D, respectively. However, considering the easiness of subsequent steps, such as dicing, the shape is desirably a rectangle, a substantial rectangle or a parallelogram since best use is made of the area of the substrate. In the case of a parallelogram as illustrated in FIG. 13E, the same advantage can be obtained even when the ratio between the length of the base and the height is made equal to the ratio between D1 and D2.

When a GaN semiconductor layer is epitaxially grown into a thickness of about 2 μm to about 10 μm both inclusive onto a sapphire substrate having a thickness of 0.5 mm to 2 mm both inclusive, it is proper that the sizes D1 and D2 of each of the semiconductor layers are each in the range of 0.5 cm to 3.0 cm both inclusive in order to restrain the deformation amount into the range of, for example, 1 μm to 2 μm both inclusive, which corresponds to the focal depth in the light-exposure step.

In many cases, a sapphire substrate is polished into a thickness of about 100 μm in a polishing step, and then elements and others are mounted onto the substrate. However, when the deformation amount of the sapphire substrate is large, the polished sapphire substrate is varied in thickness. Thus, an extremely thin region of the sapphire substrate cannot be used as a manufactured product. From such a viewpoint, it is desired to control the deformation amount of the sapphire substrate to 70 μm or less. The deformation amount is preferably 40 μm or less. For example, in the case of growing a GaN semiconductor layer epitaxially into a thickness of about 2 μm to about 10 μm both inclusive onto a sapphire substrate having a thickness of 0.5 mm to 2 mm both inclusive, it is proper that the sizes D1 and D2 of each of the semiconductor layers are each in the range of 2.8 cm to 12.5 cm both inclusive in order to restrain the deformation amount into the range of about 40 μm to about 70 μm both inclusive.

### Exemplary Embodiment 2

In the present exemplary embodiment, the sizes D1 and D2 in FIGS. 11A, 11B and 11C drawn for exemplary embodiment 1, i.e., the size D1 in the first axis direction of each of the sections of semiconductor layer 15 and the size D2 in the second axis direction thereof are defined as the following mathematical formulas 4 and 5 on the basis of the curvature radius ρ1 in the first axis direction, and that ρ2 in the second axis direction:

[Math. 4]

D1≅\sqrt{8Hₘₐₓρ1} Mathematical formula 4

[Math. 5]

D2≅\sqrt{8Hₘₐₓρ2} Mathematical formula 5

In the formulas, Hₘₐₓ represents the maximum deformation amount of the semiconductor layer section, and the value thereof can be set to a desired deformation amount. When the value is set to, for example, the focal depth of the light-exposure device, the light exposure can be attained without receiving any restriction based on a deformation of the substrate.

For example, in the case of growing a GaN semiconductor layer epitaxially into a thickness of about 2 μm to about 10 μm both inclusive onto a sapphire substrate having a thickness of 0.5 mm to 2 mm both inclusive, it is proper that the sizes D1 and D2 of the semiconductor layer are each in the range of 0.5 cm to 3.0 cm both inclusive in order to restrain the deformation amount into the range of about 1 μm to about 2 μm both inclusive.

Considering a scattering in the thickness of the sapphire substrate after the polishing step, it is desired to restrain the deformation amount of the sapphire substrate into 70 μm or less, preferably 40 μm or less. For example, in the case of growing a GaN semiconductor layer epitaxially into a thickness of about 2 μm to about 10 μm both inclusive onto a sapphire substrate having a thickness of 0.5 mm to 2 mm both inclusive, it is proper that the sizes D1 and D2 of the semiconductor layer are each in the range of 2.8 cm to 12.5 cm both inclusive.

In a method for carrying out the present exemplary embodiment, in the same manner as in exemplary embodiment 1, it is advisable to grow a crystal for a desired semiconductor layer onto the whole of a surface of a desired substrate, measure the curvature radius thereof, and then decide the sizes D1 and D2 of each of the semiconductor layers on the basis of the value of the radius, and a desired maximum deformation amount according to the mathematical formulas 4 and 5.

### Exemplary Embodiment 3

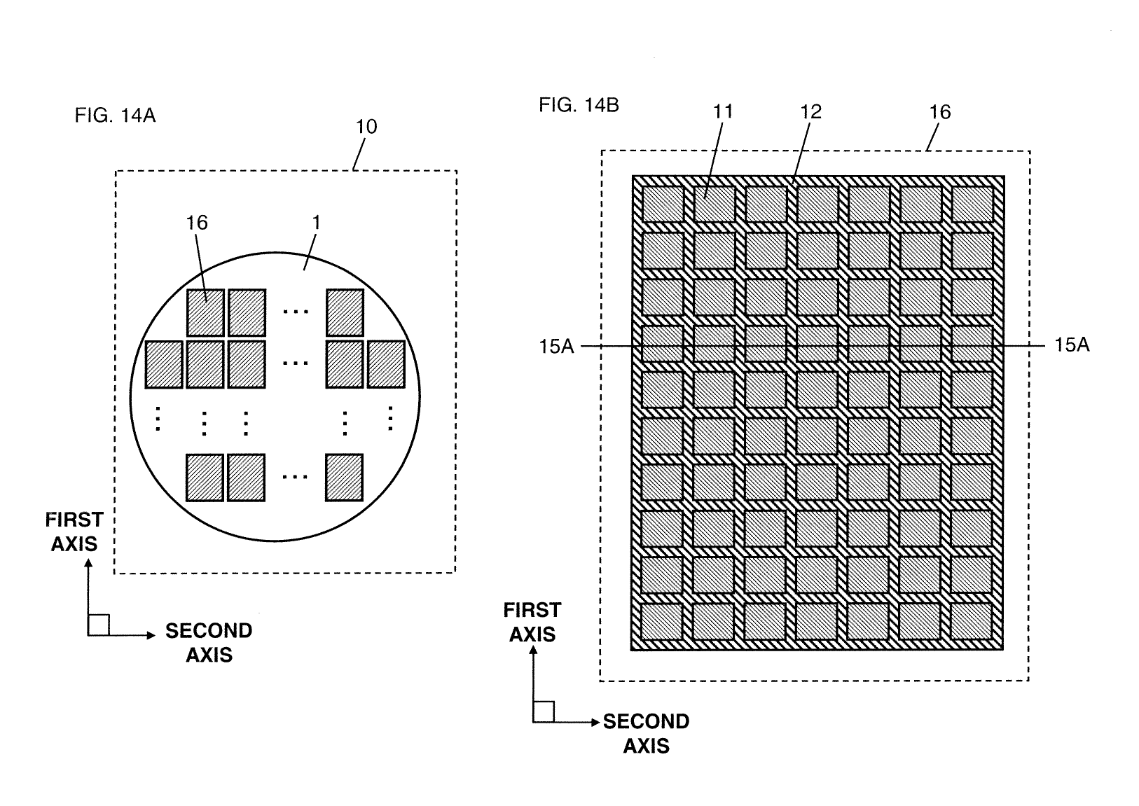

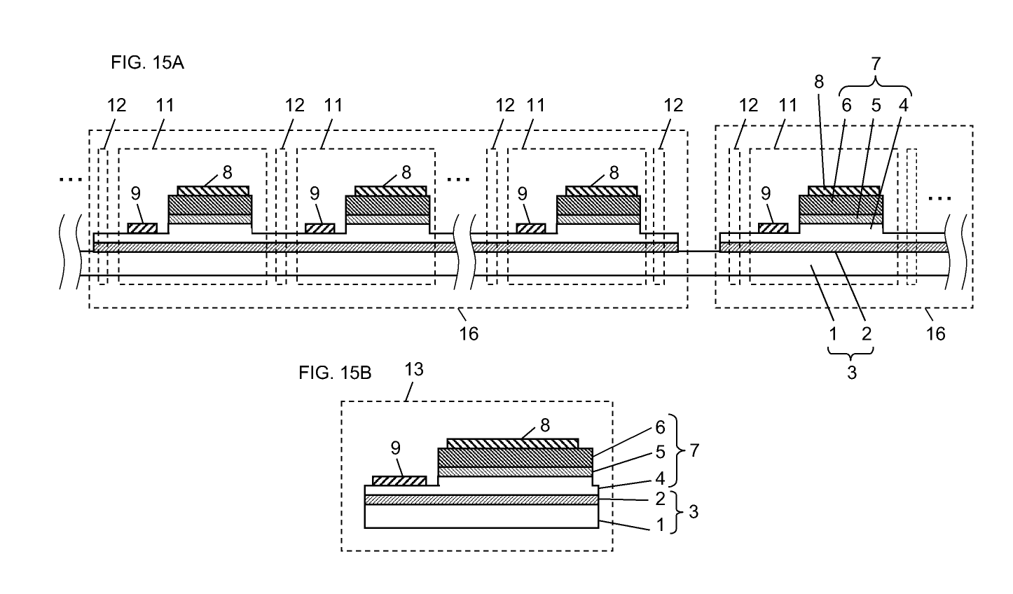

FIGS. 14A and 14B are views illustrating a semiconductor wafer of exemplary embodiment 3 according to the present invention; and FIGS. 15A and 15B are each a view illustrating semiconductor chips of exemplary embodiment 3, or one thereof. FIG. 14A is a view illustrating a principal surface of semiconductor wafer 10 when semiconductor regions 16 are formed on substrate 1. FIG. 14B is a view illustrating the principal surface of one out of semiconductor regions 16 that has a plurality of semiconductor elements 11. FIG. 15A is a cross-sectional view illustrating a portion of a cross section along line 15A-15A in FIG. 14B. FIG. 15B is a cross-sectional view of one of the semiconductor chips of exemplary embodiment 3 according to the present invention.

The semiconductor chips according to the present exemplary embodiment are each produced by use of any one of the semiconductor-stacked substrates produced in exemplary embodiments 1 and 2. As illustrated in FIG. 14A, a plurality of semiconductor regions 16, where semiconductor elements 11 that are each made of a single semiconductor element or each have a circuit structure are formed, are formed on substrate 1. Desirably, semiconductor regions 16 each having a rectangular shape are lengthways and breadthways arranged on the substrate. Semiconductor elements 11 may each be a light-emitting element such as a light-emitting diode or a semiconductor laser, or an electronic element such as a transistor or a diode, or may each be a circuit element wherein two or more thereof are connected to each other.

FIG. 14B illustrates one out of semiconductor regions 16, which has semiconductor elements 11 formed, and a scribe 12 region for separating the elements from each other. FIG. 14B is an enlarged view illustrating one out of semiconductor regions 16 produced in semiconductor wafer 10 illustrated in FIG. 14A. Semiconductor elements 11 are each desirably in a rectangular form, and are lengthways and breadthways arranged on semiconductor region 16.

FIG. 15A illustrates a partial region of the cross section taken along line 15A-15A in FIG. 14B, and some out of semiconductor elements 11 contained in semiconductor region 16 are formed on substrate 1. Semiconductor elements 11 are light-emitting diodes produced in the present exemplary embodiment.

The semiconductor wafer has, on buffer layer semiconductor-stacked structures 7 each including n-type conductive layer 4, active layer 5, and p-type conductive layer 6; sections of n-type cathode electrode layer 9 that are formed by removing p-type conductive layer 6, active layer 5 and n-type conductive layer 4 partially; and sections of p-type anode electrode layer 8 that are formed on p-type conductive layer 6.

As illustrated in FIG. 15B, semiconductor elements 11 are diced along scribe lines 12 to be divided into semiconductor chips 13.

Semiconductor chip 13 produced in this way is one out of divided chips obtained by forming a plurality of semiconductor elements 11 in semiconductor regions 16 formed by selective growth, and then dicing the workpiece. When the semiconductor chip of the present exemplary embodiment is compared with an example wherein a single semiconductor chip is produced in a single semiconductor region, or an example wherein only semiconductor active regions are selectively formed by crystal growth, and the active regions are joined to each other to cause the joined regions to act as a single chip, the present chip is not affected by any region poor in crystal quality. For this reason, an edge region of each of the semiconductor layers formed by selective growth is not scattered in composition or film thickness, so that the chip is stabilized about properties thereof. Moreover, the area of the region where the semiconductor layer is not formed (region where the pattern is formed on the basis of mask 14) can be made into a minimum level, so that the surface area of the substrate is effectively used.

Any actual m-plane does not need to be a plane completely parallel to an m-plane thereof, and may be inclined at a given angle from the m-plane. The inclination angle is determined by the angle made by the normal line of an actual principal surface of the nitride semiconductor layer and the normal line of the m-plane thereof (m-plane having no inclination angle). The actual principal surface may be inclined toward directions of vectors represented by the c-axis direction and the a-axis direction from the m-plane (m-plane having no inclination angle). The absolute value of the inclination angle θ needs only to be 5° or less, preferably 1° or less in the c-axis direction. The absolute value of the inclination angle θ needs only to be 5° or less, preferably 1° or less in the a-axis direction. In other words, in the present invention, the “m-plane” includes, in the category thereof, any plane inclined into a given direction within the range of ±5° from the m-plane (m-plane having no inclination angle). When the inclination angle is within this range, it is presumed that the principal surface of the nitride semiconductor layer is inclined, as a whole, from the m-plane but a large number of m-plane regions are microscopically made naked. Thus, any plane inclined at an angle having an absolute value of 5° or less from the m-plane would have properties equivalent to those of the m-plane. By setting the absolute value of the inclination angle θ to 5° or less, the semiconductor element or chip can be reduced in internal quantum efficiency deterioration based on a piezoelectric field.

The semiconductor-stacked substrate and the semiconductor chip disclosed in the present specification are a substrate and a chip each obtained by forming a mask pattern onto a different-species-material substrate, and then forming semiconductor layers thereon by selective growth. By setting the size ratio and the size of each of the semiconductor layers on the basis of curvature radii of the substrate, the substrate can be made even in in-plane deformation amount. This matter makes it possible to prevent inconveniences of elements that are caused in a light-exposure step or a polishing step for a large-diameter substrate.

### INDUSTRIAL APPLICABILITY

The semiconductor-stacked substrates according to the embodiments of the present invention are usable for, for example, display devices, lighting devices, light sources for LCD backlights, and others.

### REFERENCE MARKS IN THE DRAWINGS

1 substrate
2 buffer layer
3 semiconductor-stacked substrate
4 n-type conductive layer
5 active layer
6 p-type conductive layer
7 semiconductor-stacked structure
8 p-type anode electrode layer
9 n-type cathode electrode layer
10 semiconductor wafer
11 semiconductor element
12 scribe line
13 semiconductor chip
14 mask
15 semiconductor layer
16 semiconductor region

1. A semiconductor-stacked substrate, comprising:
a substrate; and
a plurality of semiconductor layers each different in thermal expansion coefficient from the substrate, and formed on a surface of the substrate, wherein
each of the semiconductor layers has a growth plane that is a nonpolar plane or a semi-polar plane;
each of the semiconductor layers has different thermal expansion coefficients between along a first axis and a second axis which are orthogonal to each other;
the first axis and the second axis are parallel to the surface of the substrate; and
the following mathematical formula 1 is satisfied:
$$\begin{matrix}Mathematical formula 1 & \\ 0. 8 D 1 \leq D 2 \frac{\sqrt{ρ 1}}{\sqrt{ρ 2}} \leq 1. 2 D 1 & [ Math . 1 ]\end{matrix}$$
where
D1 represents a length of each of the semiconductor layers in a direction parallel to the first axis, the direction passing through a point where a deformation amount of each of the semiconductor layers is largest;
D2 represents a length of each of the semiconductor layers in a direction parallel to the second axis, the direction passing through a point where a deformation amount of each of the semiconductor layers is greatest;
ρ1 represents a curvature radius of each of the semiconductor layers in a direction parallel to the first axis, the direction passing through a point where a deformation amount of each of the semiconductor layers is greatest; and
ρ2 represents a curvature radius of each of the semiconductor layers in a direction parallel to the second axis, the direction passing through a point where a deformation amount of each of the semiconductor layers is greatest.

2. A semiconductor-stacked substrate, comprising;
a substrate; and
a plurality of semiconductor layers formed on a surface of the substrate, wherein
each of the semiconductor layers has a growth plane that is a nonpolar plane or a semi-polar plane;
different stresses are generated between along a first axis and a second axis which are orthogonal to each other,
the first axis and the second axis are parallel to the surface of the substrate; and
the following mathematical formula 1 is satisfied;
$$\begin{matrix}Mathematical formula 1 & \\ 0. 8 D 1 \leq D 2 \frac{\sqrt{ρ 1}}{\sqrt{ρ 2}} \leq 1. 2 D 1 & [ Math . 1 ]\end{matrix}$$
where
D1 represents a length of each of the semiconductor layers in a direction parallel to the first axis, the direction passing through a point where a deformation amount of each of the semiconductor layers is largest;
D2 represents a length of each of the semiconductor layers in a direction parallel to the second axis, the direction passing through a point where a deformation amount of each of the semiconductor layers is greatest;
ρ1 represents a curvature radius of each of the semiconductor layers in a direction parallel to the first axis, the direction passing through a point where a deformation amount of each of the semiconductor layers is greatest; and
ρ2 represents a curvature radius of each of the semiconductor layers in a direction parallel to the second axis, the direction passing through a point where a deformation amount of each of the semiconductor layers is greatest.

3. The semiconductor-stacked substrate according to claim 2, wherein the stresses include distortion stress.

4. The semiconductor-stacked substrate according to claim 1, wherein the lengths D1 and D2 are different from each other, and radii ρ1 and ρ2 are different from each other.

5. The semiconductor-stacked substrate according to claim 1, wherein a ratio D1/D2 of the length D1 to the length D2 is defined as the following mathematical formula 3:
$$\begin{matrix}Mathematical formula 3 & \\ \frac{D 1}{D 2} = \frac{\sqrt{ρ 1}}{\sqrt{ρ 2}} & [ Math . 3 ]\end{matrix}$$

6. The semiconductor-stacked substrate according to claim 1, wherein the length D1 is defined, using the radius ρ1 and the maximum deformation amount Hₘₐₓ of each of the semiconductor layers as the following mathematical formula 4:
[Math. 4]
D1≅\sqrt{8Hₘₐₓρ1} Mathematical formula 4

7. The semiconductor-stacked substrate according to claim 1, wherein the length D2 is defined, using the radius ρ2 and the maximum deformation amount Hₘₐₓ of the each of semiconductor layers as the following mathematical formula 5:
[Math. 5]
D2≅\sqrt{8Hₘₐₓρ2} Mathematical formula 5

8. The semiconductor-stacked substrate according to claim 6, wherein a center of each of the semiconductor layers has the maximum deformation amount Hₘₐₓ.

9. The semiconductor-stacked substrate according to claim 1, wherein the substrate is a sapphire substrate.

10. The semiconductor-stacked substrate according to claim 1, wherein the surface of the substrate is an m-plane, the first axis is an a-axis, and the second axis is a c-axis.

11. The semiconductor-stacked substrate according to claim 1, wherein the surface of the substrate is an a-plane, the first axis is an a-axis, and the second axis is a c-axis.

12. The semiconductor-stacked substrate according to claim 1, wherein the growth plane of the semiconductor layers is an m-plane, the first axis is an a-axis, and the second axis is a c-axis.

13. The semiconductor-stacked substrate according to claim 1, wherein the semiconductor layers are GaN based semiconductor layer sections.

14. The semiconductor-stacked substrate according to claim 1, wherein the semiconductor layers comprise AlₓGa_{y}In_{z}N wherein x+y+z=1, and x≧0, y≧0, and z≧0.

15. The semiconductor-stacked substrate according to claim 1, wherein the lengths D1 and D2 are each from 0.5 cm to 3 cm both inclusive.

16. The semiconductor-stacked substrate according to claim 1, wherein the lengths D1 and D2 are each from 2.8 cm to 12.5 cm both inclusive.

17. The semiconductor-stacked substrate according to claim 1, wherein when the surface of each of the semiconductor layers is viewed from above, the shape of the surface has two sides substantially parallel to the first axis, and two sides substantially parallel to the second axis.

18. A semiconductor chip out of semiconductor chips produced by using the semiconductor layers of the semiconductor-stacked substrate recited in claim 1 to produce a plurality of semiconductor elements or semiconductor circuit elements, and dividing the semiconductor elements or semiconductor circuit elements from each other.

19. A method for producing a semiconductor-stacked substrate comprising a substrate and a plurality of semiconductor layers each different in thermal expansion coefficient from the substrate,
the method comprising:
a step (A) of forming, on the substrate, a mask having a plurality of openings; and
a step (B) of forming the plurality of semiconductor layers in the plurality of openings, wherein
in the step (A), each of the semiconductor layers has a growth plane that is a nonpolar plane or a semi-polar plane;
each of the semiconductor layers has different thermal expansion coefficients between along a first axis and a second axis which are orthogonal to each other;
the first axis and the second axis are parallel to the surface of the substrate; and
the following mathematical formula 2 is satisfied:
$$\begin{matrix}Mathematical formula 2 & \\ 0. 8 D 1 \leq D 2 \frac{\sqrt{ρ 1}}{\sqrt{ρ 2}} \leq 1. 2 D 1 & [ Math . 2 ]\end{matrix}$$
where
D1 represents a length of each of the semiconductor layers in a direction parallel to the first axis;
D2 represents a length of each of the semiconductor layers in a direction parallel to the second axis;
ρ1 represents a curvature radius of each of the semiconductor layers in a direction parallel to the first axis; and
ρ2 represents a curvature radius of each of the semiconductor layers in a direction parallel to the second axis.

20. A method for producing a semiconductor-stacked substrate comprising a substrate and a plurality of semiconductor layers,
the method comprising:
a step (A) of forming, on the substrate, a mask having a plurality of openings; and
a step (B) of forming the plurality of semiconductor layers in the plurality of openings, wherein
in the step (A), each of the semiconductor layers has a growth plane that is a nonpolar plane or a semi-polar plane;
different stresses are generated between along a first axis and a second axis which are orthogonal to each other;
the first axis and the second axis are parallel to the surface of the substrate; and
the following mathematical formula 2 is satisfied:
$$\begin{matrix}Mathematical formula 2 & \\ 0. 8 D 1 \leq D 2 \frac{\sqrt{ρ 1}}{\sqrt{ρ 2}} \leq 1. 2 D 1 & [ Math . 2 ]\end{matrix}$$
where
D1 represents a length of each of the semiconductor layers in a direction parallel to the first axis;
D2 represents a length of each of the semiconductor layers in a direction parallel to the second axis;
ρ1 represents a curvature radius of each of the semiconductor layers in a direction parallel to the first axis; and
ρ2 represents a curvature radius of each of the semiconductor layers in a direction parallel to the second axis.
